(19) United States
(12) Patent Application Publication
(10) Pub. No.: US 2025/0014926 A1
(43) Pub. Date: Jan. 9, 2025

(54) SAMPLE MEASURING APPARATUS

(71) Applicant: KONICA MINOLTA, INC., Tokyo (JP)

(72) Inventors: Yusuke MURAKAMI, Tokyo (JP); Takumi SAKURADA, Tokyo (JP); Katsunori TAKAHASHI, Tokyo (JP)

(73) Assignee: KONICA MINOLTA, INC., Tokyo (JP)

(21) Appl. No.: 18/752,815

(22) Filed: Jun. 25, 2024

(30) Foreign Application Priority Data
Jul. 6, 2023 (JP) 2023-111177
Jul. 6, 2023 (JP) 2023111178

(51) Int. Cl. H01L 21/67; H01L 21/673; H01L 21/677

(52) U.S. Cl. CPC H01L 21/67265; H01L 21/67346; H01L 21/67778

(57) ABSTRACT

The sample measuring apparatus includes: a measuring device that measures a sample; a conveyance device that uses cassettes each having a plurality of stages capable of storing a plurality of samples having different sizes, takes out each sample one by one from a cassette serving as a pickup source among the cassettes, conveys the sample to the measuring device, and stores the sample measured by the measuring device into a cassette serving as a placement destination among the cassettes; a sample detector capable of detecting presence or absence of the sample in each stage of each of the cassettes; and a controller that controls the measuring device and the conveyance device based on a result of the detection by the sample detector.

### CROSS-REFERENCE TO RELATED APPLICATION

The entire disclosure of Japanese patent Application No. 2023-111177 and No. 2023-111178, filed on Jul. 6, 2023, is incorporated herein by reference in its entirety.

### BACKGROUND OF THE INVENTION

### 1. Technical Field

The present invention relates to a sample measuring apparatus.

### 2. Description of Related Art

A sample measuring apparatus needs to include a measuring device and a conveyance device in order to sequentially and automatically measure samples having different sizes. The measuring device measures the samples. The conveyance device conveys the samples.

Japanese Unexamined Patent Application Publication No. 2006-185345 describes a technique for using a pressure sensor to determine whether or not a workpiece is placed on a pallet conveyed by a conveyor. The pressure sensor is provided at the center of the pallet. The pressure sensor outputs a signal corresponding to the weight of the workpiece placed on the pallet.

### SUMMARY OF THE INVENTION

When a sample is measured using the above-described sample measuring apparatus, a user installs a cassette for storing an unmeasured sample and a cassette for storing a measured sample in predetermined places. In the following description, a cassette for storing an unmeasured sample is also referred to as a “cassette serving as a pickup source”, and a cassette for storing the measured sample is also referred to as a “cassette serving as a placement destination”.

In a cassette having a plurality of stages, a plurality of samples having different sizes can be loaded at positions shifted in a top/bottom direction. A user sets sample information in advance from an operation part of the sample measuring apparatus. The sample information is information including the size of a sample stored in each stage of a cassette serving as a pickup source.

In a case where the above-described conveyance device takes out an unmeasured sample from a cassette serving as a pickup source, a hand portion or the like of the conveyance device may collide with the sample due to a mistake of a user, and the sample may be damaged. As the user's mistake in this case, for example, a mistake in which the user mistakenly sets the position of an unmeasured sample when the user sets the sample in the cassette serving as a pickup source is conceivable.

Furthermore, also in a case where the above-described conveyance device stores a measured sample into a cassette serving as a placement destination, the hand portion or the like of the conveyance device may collide with the sample due to a mistake of the user, and the sample may be damaged. As the user's mistake in this case, for example, a mistake in which the user forgets to take a sample when the user needs to take out in advance all samples from a cassette to be used as a cassette serving as a placement destination is conceivable.

In a case where the above-described conveyance device takes out a sample from the cassette serving as a pickup source, a sample size error may occur. The sample size error means that when the conveyance device takes out a sample from a takeout target stage of the cassette serving as a pickup source, the size of the sample stored in the takeout target stage is different from a sample size set for the takeout target stage. The sample size error is caused by a user's mistake. In a case where the sample size error occurs, the above-described conveyance device may not be able to appropriately handle the sample, and various problems may occur.

An object of the present invention is to provide a sample measuring apparatus capable of preventing a sample from being damaged due to a user's mistake.

According to a first aspect of the present invention, a sample measuring apparatus includes: a measuring device that measures a sample; a conveyance device that uses cassettes each having a plurality of stages capable of storing a plurality of samples having different sizes, takes out each sample one by one from a cassette serving as a pickup source among the cassettes, conveys the sample to the measuring device, and stores the sample measured by the measuring device into a cassette serving as a placement destination among the cassettes; a sample detector capable of detecting presence or absence of the sample in each stage of each of the cassettes; and a controller that controls the measuring device and the conveyance device based on a result of the detection by the sample detector.

According to a second aspect of the present invention, a sample measuring apparatus includes: a measuring device that measures a sample; a conveyance device that takes out each sample one by one from a cassette having a plurality of stages capable of storing a plurality of samples having different sizes, and conveys the sample to the measuring device; a size detector that detects a size of the sample stored in each stage of the cassette; and a controller that controls the measuring device and the conveyance device based on a result of the detection by the size detector.

### BRIEF DESCRIPTION OF THE DRAWINGS

The advantages and features provided by one or more embodiments of the invention will become more fully understand from the detailed description given hereinbelow and the appended drawings which are given by way of illustration only, and thus are not intended as a definition of the limits of the present invention.

FIG. 1 is a schematic perspective view illustrating a configuration of a sample measuring apparatus according to a first embodiment of the present invention;

FIG. 2 is a schematic plan view illustrating the configuration of the sample measuring apparatus according to the first embodiment of the present invention;

FIG. 3 is a schematic perspective view illustrating a configuration of a cassette;

FIG. 4 is a schematic plan view illustrating a configuration of each cassette;

FIG. 5 is a schematic side view illustrating a configuration of a hand portion of a conveyance device;

FIG. 6 is a diagram for explaining an example of setting a length of a pressing member illustrated in FIG. 5;

FIG. 7 is a schematic plan view illustrating a state in which the hand portion of the conveyance device is entered into the cassette;

FIG. 8 is a block diagram illustrating a configuration of a control system of the sample measuring apparatus according to the first embodiment of the present invention;

FIG. 9 is a diagram (part 1) for explaining a method of detecting the presence or absence of a sample using the pressing member;

FIG. 10 is a diagram (part 2) for explaining the method of detecting the presence or absence of a sample using the pressing member;

FIG. 11 is a flowchart illustrating an example of a processing procedure for measuring a sample using the sample measuring apparatus according to the first embodiment of the present invention;

FIG. 12 is a schematic diagram illustrating a cassette serving as a pickup source and a cassette serving as a placement destination;

FIG. 13 is a schematic diagram illustrating an example of conveying a sample from the cassette serving as the pickup source to the cassette serving as the placement destination;

FIG. 14 is a schematic diagram (part 1) for explaining an example in which a sample is measured by the sample measuring apparatus using three cassettes;

FIG. 15 is a schematic diagram (part 2) illustrating an example in which a sample is measured by the sample measuring apparatus using the three cassettes;

FIG. 16 is a schematic diagram (part 3) illustrating an example in which a sample is measured by the sample measuring apparatus using the three cassettes;

FIG. 17 is a schematic diagram (part 4) illustrating an example in which a sample is measured by the sample measuring apparatus using the three cassettes;

FIG. 18 is a schematic diagram (part 5) illustrating an example in which a sample is measured by the sample measuring apparatus using the three cassettes;

FIG. 19 is a schematic diagram (part 6) illustrating an example in which a sample is measured by the sample measuring apparatus using the three cassettes;

FIG. 20 is a schematic diagram (part 7) for explaining an example in which a sample is measured by a sample measuring apparatus using the three cassettes;

FIG. 21 is a diagram (part 1) illustrating a distance measuring sensor included in a sample detector according to a second embodiment of the present invention;

FIG. 22 is a diagram (part 2) illustrating the distance measuring sensor included in the sample detector according to the second embodiment of the present invention;

FIG. 23 is a diagram illustrating an imager included in the sample detector according to a third embodiment of the present invention;

FIG. 24 is a diagram (part 1) illustrating an example in which each of sample detection sensors included in a sample detector according to a fourth embodiment of the present invention is a contact-type sensor;

FIG. 25 is a diagram (part 2) illustrating an example in which each of the sample detection sensors included in the sample detector according to the fourth embodiment of the present invention is the contact-type sensor;

FIG. 26 is a diagram (part 1) illustrating an example in which each of the sample detection sensors included in the sample detector according to the fourth embodiment of the present invention is a non-contact sensor;

FIG. 27 is a diagram (part 2) illustrating an example in which each of the sample detection sensors included in the sample detector according to the fourth embodiment of the present invention is the non-contact sensor;

FIG. 28 is a block diagram illustrating a configuration of a control system of a sample measuring apparatus according to a fifth embodiment of the present invention;

FIG. 29 is a flowchart illustrating an example of a processing procedure for measuring a sample using the sample measuring apparatus according to the fifth embodiment of the present invention;

FIG. 30 is a schematic side view illustrating an arrangement state of a pressing member;

FIG. 31 is a schematic side view illustrating a state in which the pressing member is in contact with a sample;

FIG. 32 is a schematic side view illustrating a state in which the sample is pressed against a reference end portion by the pressing member;

FIG. 33 is a schematic side view for explaining a relationship between the position of the pressing member and a minimum sample size;

FIG. 34 is a schematic plan view illustrating a state in which a sample is pressed against a side plate portion of a cassette;

FIG. 35 is a schematic side view (part 1) illustrating the inclination angle of the pressing member;

FIG. 36 is a schematic side view (part 2) illustrating the inclination angle of the pressing member;

FIG. 37 is a diagram for explaining a problem caused by a sample size error;

FIG. 38 is a flowchart illustrating a modification example of the processing procedure for measuring a sample using the sample measuring apparatus according to the fifth embodiment of the present invention;

FIG. 39 is a block diagram illustrating a configuration of a control system of a sample measuring apparatus according to a sixth embodiment of the present invention;

FIG. 40 is a diagram illustrating an example of a table;

FIG. 41 is a flowchart illustrating an example of a processing procedure for measuring a sample using the sample measuring apparatus according to the sixth embodiment of the present invention;

FIG. 42 is a schematic plan view illustrating an example in which each of size detection sensors is an array sensor; and

FIG. 43 is a schematic plan view illustrating an example in which each of size detection sensors is a pressure distribution sensor.

### DETAILED DESCRIPTION

Hereinafter, one or more embodiments of the present invention will be described with reference to the drawings. However, the scope of the invention is not limited to the disclosed embodiments.

In this specification and the drawings, elements having substantially the same functions or configurations are denoted by the same reference signs, and redundant description will be omitted as appropriate. Furthermore, the following description and the drawings are examples for explaining the present invention and may be omitted or simplified for convenience of explanation. Each constituent element may be singular or plural unless otherwise specified. Furthermore, the position, size, shape, range, and the like of each constituent element illustrated in the drawings may not represent the actual position, size, shape, range, and the like in order to facilitate understanding of the invention. Therefore, the present invention is not necessarily limited to the positions, sizes, shapes, ranges, and the like disclosed in the drawings.

### First Embodiment

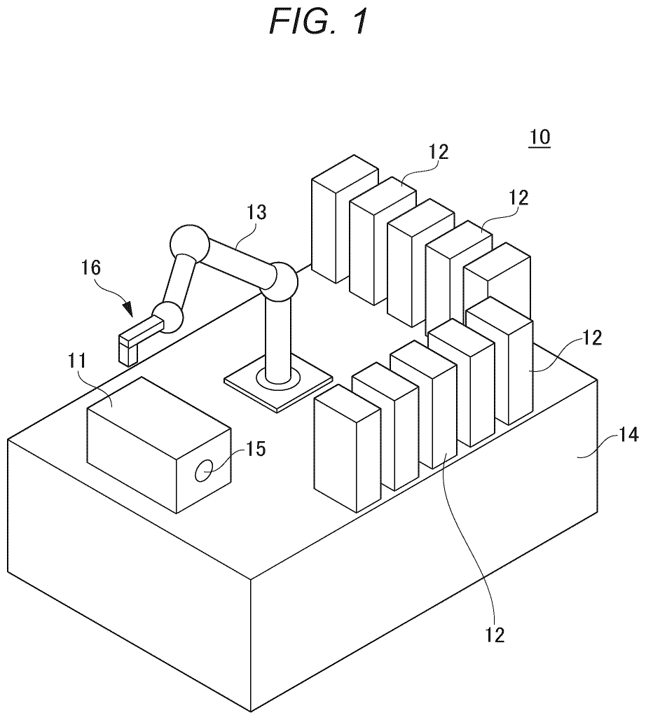

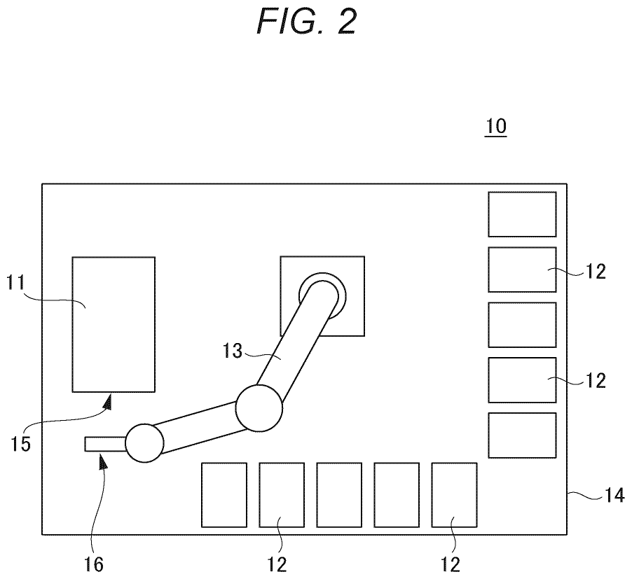

FIG. 1 is a schematic perspective view illustrating a configuration of a sample measuring apparatus according to a first embodiment of the present invention. FIG. 2 is a schematic plan view illustrating the configuration of the sample measuring apparatus according to the first embodiment of the present invention.

As illustrated in FIGS. 1 and 2, the sample measuring apparatus 10 includes a measuring device 11, a conveyance device 13, and a base 14. The measuring device 11 is a device for measuring a sample (not illustrated). The conveyance device 13 takes out each unmeasured sample one by one from a cassette 12 serving as a pickup source and conveys the sample to the measuring device 11. The conveyance device 13 stores the sample measured by the measuring device 11 into a cassette 12 serving as a placement destination. The sample measuring apparatus 10 can sequentially and automatically measure samples having different sizes. The measuring device 11 and the conveyance device 13 are installed on the base 14.

The measuring device 11 includes a measurement section 15. The measurement section 15 measures a sample for a predetermined measurement item. For example, in a case where the measuring device 11 is a device for measuring a surface condition of a sample, the measurement section 15 measures the surface condition of the sample. The surface condition of the sample refers to at least one of the color, surface properties, and glossiness of the sample. The surface properties of the sample are typically the surface roughness of the sample. In the present embodiment, as an example, the measuring device 11 is a device that measures the color of a sample, that is, a colorimeter. A sample to be measured is arranged in a state in which a surface of the sample to be measured is arranged close to and faces the measurement section 15 of the measuring device 11. The surface of the sample to be measured is the surface of the sample to be measured (measured) by the measurement section 15 of the measuring device 11.

Each of the cassettes 12 can store a plurality of samples. The cassettes 12 may be elements that form the sample measuring apparatus 10 together with the measuring device 11 and the conveyance device 13. A plurality of samples having different sizes can be stored in each of the cassettes 12. The sample to be measured is typically a plate-shaped sample, and more typically a flat plate-shaped sample.

The samples having different sizes may be samples having the same shape or samples having different shapes. The shape of each sample refers to the shape of the plate-like sample as viewed from the front, in other words, the shape of the horizontally placed sample in plan view. In the present embodiment, as an example, a plate-like sample having a quadrangular shape (e.g., a rectangular shape or a square shape) in plan view is a measurement target. The sample is formed of a material that does not substantially transmit visible light or the like, that is, an opaque material.

Here, the reason why each cassette 12 that can store a plurality of samples having different sizes is used will be described.

In a case where only samples having the same size are stored in one cassette 12, it is necessary to prepare a dedicated cassette 12 for each of sizes of samples. As a specific example, a case where 50 samples can be stored in each cassette 12 is considered. In this case, in a case where at least one sample having a different size is included in samples to be measured, samples having different sizes must be stored separately in two cassettes 12. As a result, the cassette 12 storing only one sample occupies the same area as that of the cassette capable of storing 50 samples. Therefore, the number of samples that can be placed on the sample measuring apparatus 10 as a whole is reduced.

On the other hand, in a case where the cassettes 12 each capable of storing a plurality of samples having different sizes are used, the above-described sample having the different size can be collectively stored in one cassette 12 together with the other samples. Therefore, in a case where the cassettes 12 each capable of storing a plurality of samples having different sizes are used, it is possible to increase the number of samples which can be placed on the sample measuring apparatus 10 as a whole, compared to a case where only samples having the same size are stored in one cassette 12.

For the above-described reasons, the cassettes 12 each capable of storing a plurality of samples having different sizes are used in the present embodiment.

The plurality of cassettes 12 are installed on the base 14. Each of the cassettes 12 is removably installed on the base 14. An unmeasured sample or a measured sample is stored in each cassette 12. The number of cassettes 12 that can be installed on the base 14 can be changed. In FIG. 2, as an example, a total of ten cassettes 12 are installed on the base 14.

In a case where a sample is automatically measured by using the sample measuring apparatus 10, at least two cassettes 12 are installed on the base 14. In this case, one of the cassettes 12 is a cassette 12 serving as a pickup source, and the other of the cassettes 12 is a cassette 12 serving as a placement destination.

Each of the cassettes 12 has a plurality of stages capable of storing a plurality of samples having different sizes. One sample is stored in one stage. Therefore, each of the cassettes 12 can store a plurality of samples in the states in which the samples are loaded at predetermined intervals in a top/bottom direction. In other words, each of the cassettes 12 can store a plurality of samples arranged in the plurality of stages (multiple stages) in the top/bottom direction. In the present embodiment, as an example, it is assumed that a plurality of samples having different sizes are mixed in each of the cassettes 12. In each stage of each of the cassettes 12, a sample is stored with a surface directed downward and to be measured.

The conveyance device 13 sequentially takes out the samples from the cassette 12 serving as the pickup source and conveys the samples to the measuring device 11. The conveyance device 13 sequentially stores the samples that have been measured by the measuring device 11, that is, the measured samples into the cassette 12 serving as the placement destination. The conveyance device 13 is constituted by a multi-axis robot. In the present embodiment, as an example, the conveyance device 13 is constituted by a six-axis robot. The conveyance device 13, which is the six-axis robot, includes a force sensor (not illustrated). The force sensor measures the magnitude of force or torque acting on the conveyance device 13 in real time. In the present embodiment, as an example, the conveyance device 13 includes a six-axis force sensor.

The conveyance device 13 includes a hand portion 16 for holding a sample. The hand portion 16 is disposed at a distal end portion of the six-axis robot serving as the conveyance device 13. The conveyance device 13 holds, one by one, unmeasured samples stored in the cassette 12 serving as the pickup source, with the hand portion 16. The conveyance device 13 conveys a sample held by the hand portion 16 toward the measurement section 15 of the measuring device 11. In addition, the conveyance device 13 aligns the sample with the measurement section 15 of the measuring device 11 and arranges the sample. When the measurement section 15 completes the measurement of the color of the sample, the conveyance device 13 conveys the sample toward the cassette 12 serving as the placement destination, and stores the sample into the cassette 12 serving as the placement destination. The cassette 12 serving as the pickup source is a cassette from which a sample to be measured by the measuring device 11 is to be taken out. The cassette 12 serving as the placement destination is a cassette into which the sample measured by the measuring device 11 is to be stored. Both the cassette 12 serving as the pickup source and the cassette 12 serving as the placement destination have a common cassette structure having a plurality of stages.

The cassette 12 serving as the pickup source and the cassette 12 serving as the placement destination are separately designated.

Therefore, a sample taken out from one of the cassettes 12 is stored in the other cassette 12 after the measuring device 11 completes the measurement of the sample. In addition, the cassette 12 serving as the pickup source and the cassette 12 serving as the placement destination are arranged at adjacent positions on the base 14. Furthermore, the cassette 12 that has been emptied after all unmeasured samples have been taken out from the cassette 12 may be used later as a cassette for storing measured samples, that is, as the cassette 12 serving as a placement destination. In other words, the cassette 12 serving as the pickup source may be subsequently switched to the cassette 12 serving as a placement destination. In addition, in a case where a plurality of samples 30 are stored in the cassette 12 serving as the pickup source, the conveyance device 13 takes out the samples 30 one by one from an upper stage to a lower stage of the cassette 12 serving as the pickup source. When the samples 30 are to be stored in the cassette 12 serving as the placement destination, the conveyance device 13 stores the samples 30 into the cassette 12 serving as the placement destination from a lower stage to an upper stage of the cassette 12 serving as the placement destination.

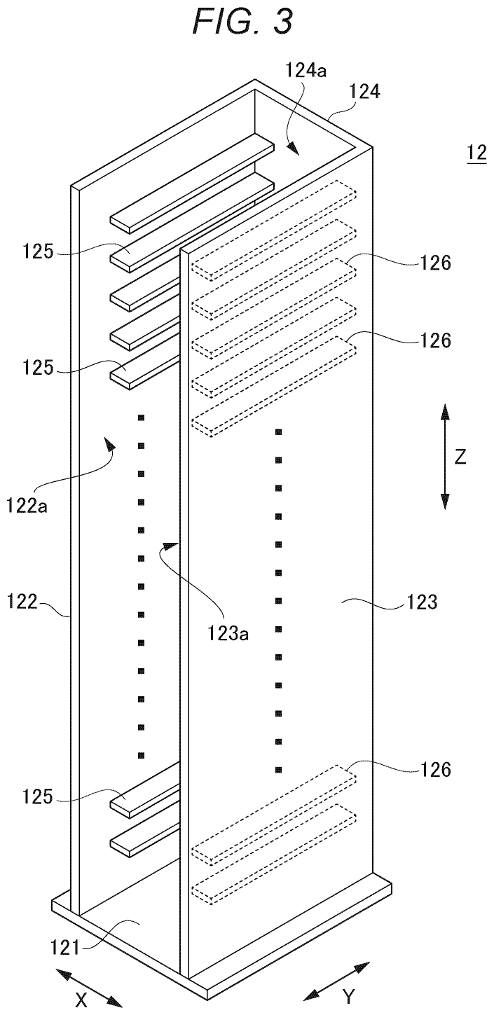

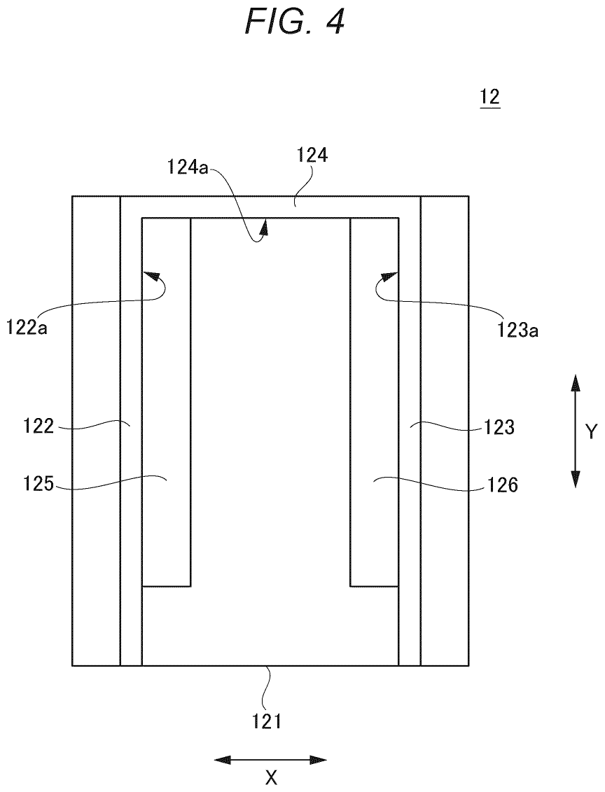

FIG. 3 is a schematic perspective view illustrating a configuration of a cassette; FIG. 4 is a schematic plan view illustrating a configuration of each of the cassettes. In FIGS. 3 and 4, in order to clarify a positional relationship or the like of each portion of the cassette 12, a width direction of the cassette 12 is set as an X direction, a depth direction of the cassette 12 is set as a Y direction, and a height direction of the cassette 12 is set as a Z direction. In the following description, the width direction of the cassette 12 is also referred to as a “width direction X of the cassette”. The depth direction of the cassette 12 is also referred to as “depth direction Y of the cassette” and the height direction of the cassette 12 is also referred to as “height direction Z of the cassette”. Samples can be taken out from and stored into the cassette 12 in the depth direction Y of the cassette 12. The front side of the cassette 12 is open such that samples can be taken out from and stored into the cassette 12. In a state in which the cassette 12 is installed on the base 14, the width direction X of the cassette 12 and the depth direction Y of the cassette 12 are substantially parallel to a horizontal direction. In addition, in a state in which the cassette 12 is installed on the base 14, the height direction Z of the cassette 12 is a direction substantially parallel to a vertical direction. In the height direction Z of the cassette 12, a lower portion of the cassette 12 is closed by a bottom plate portion 121. In the height direction Z of the cassette 12, an upper portion of the cassette 12 is open. The reason why the upper portion of the cassette 12 is open is to avoid interference between the cassette 12 and the hand portion 16 of the conveyance device 13.

As illustrated in FIGS. 3 and 4, the cassette 12 includes a bottom plate portion 121, a pair of side plate portions 122 and 123, and a back plate portion 124. The pair of side plate portions 122 and 123 stand vertically from the bottom plate portion 121. The pair of side plate portions 122 and 123 is coupled by the back plate portion 124. The bottom plate portion 121 is disposed at the lowermost portion of the cassette 12 in the height direction Z. The pair of side plate portions 122 and 123 are arranged to face each other in the width direction X of the cassette 12. The back plate portion 124 is disposed on the back side in the depth direction Y of the cassette 12. The back plate portion 124 has substantially the same height dimension as that of the pair of side plate portions 122 and 123. An inner surface 124a of the back plate portion 124 is disposed so as to face the front side of the cassette 12 in the depth direction Y of the cassette 12.

Inner surfaces 122a and 123a of the pair of side plate portions 122 and 123 are arranged to face each other in the width direction X of the cassette 12. A plurality of support portions 125 are provided on the inner surface 122a of the side plate portion 122. A plurality of support portions 126 are provided on the inner surface 123a of the side plate portion 123. The plurality of support portions 125 are disposed at predetermined intervals in the height direction Z of the cassette 12. The plurality of support portions 126 are disposed at predetermined intervals in the height direction Z of the cassette 12. When a plurality of samples are loaded and stored in a plurality of stages in one cassette 12, the plurality of support portions 125 and the plurality of support portions 126 support the samples in a placed state in each stage. One stage in the cassette 12 includes one support portion 125 and one support portion 126 arranged at the same position in the height direction Z of the cassette 12.

Furthermore, the support portions 125 and 126 that form a pair and support a sample in the same stage are arranged to face each other in the width direction X of the cassette 12. Each of the support portions 125 is formed in a flat plate shape that is long in the depth direction Y of the cassette 12. In addition, each of the support portions 125 is disposed so as to protrude from the inner surface 122a of the side plate portion 122 toward the center of the cassette 12 in the width direction X. Similarly to the support portions 125, each of the support portions 126 is formed in a flat plate shape that is long in the depth direction Y of the cassette 12. In addition, each of the support portions 126 is disposed so as to protrude from the inner surface 123a of the side plate portion 123 toward the center of the cassette 12 in the width direction X. A sample stored in the cassette 12 is supported in a horizontal posture in a state in which both end portions of a surface of the sample to be measured are placed on the upper surfaces of the pair of support portions 125 and 126.

In the present embodiment, as the configuration of each of the cassettes 12 having the plurality of stages, a configuration in which the plurality of support portions 125 are provided on the inner surface 122a of the side plate portion 122 and the plurality of support portions 126 are provided on the inner surface 123a of the side plate portion 123 is employed. However, the configuration of the cassette is not limited to the configuration illustrated in FIG. 3 and FIG. 4. For example, each of the cassettes 12 may have a configuration in which a plurality of grooves are formed in each of the inner surfaces 122a and 123a of the pair of side plate portions 122 and 123.

The plurality of grooves are grooves for supporting a plurality of samples in multiple stages in the height direction Z of the cassette. The plurality of grooves are formed at predetermined intervals in the height direction Z of the cassette.

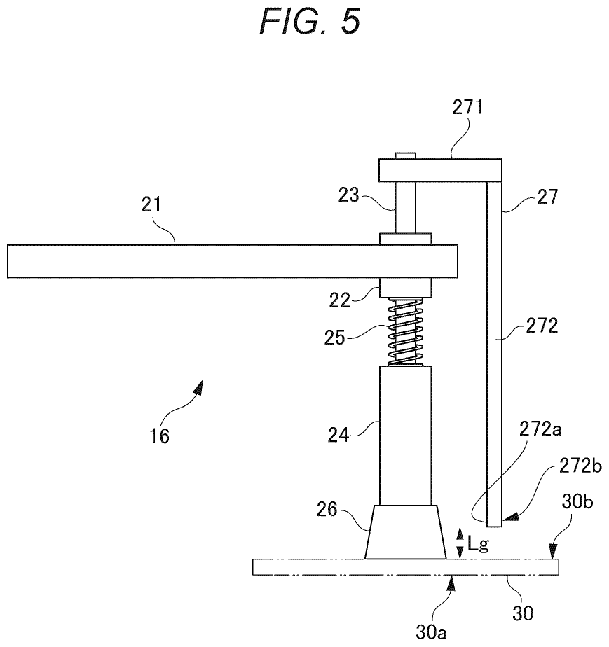

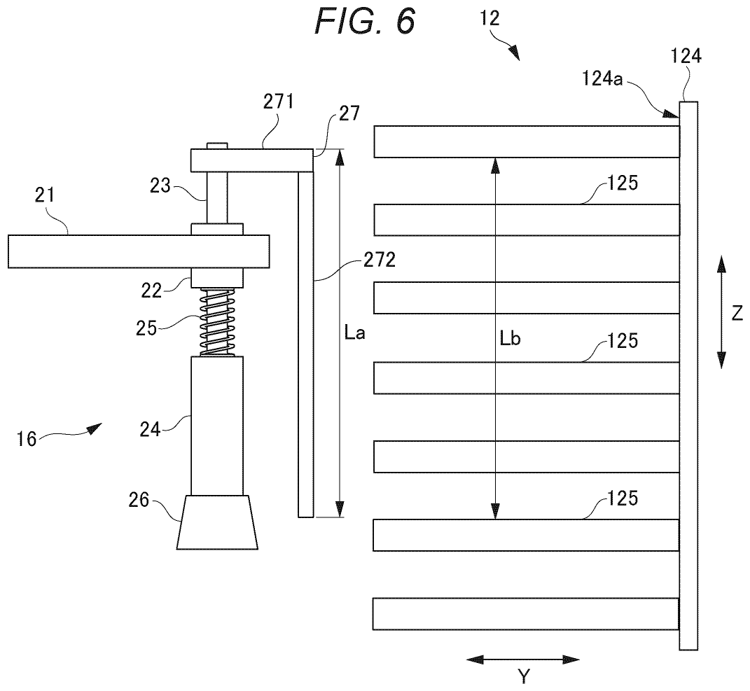

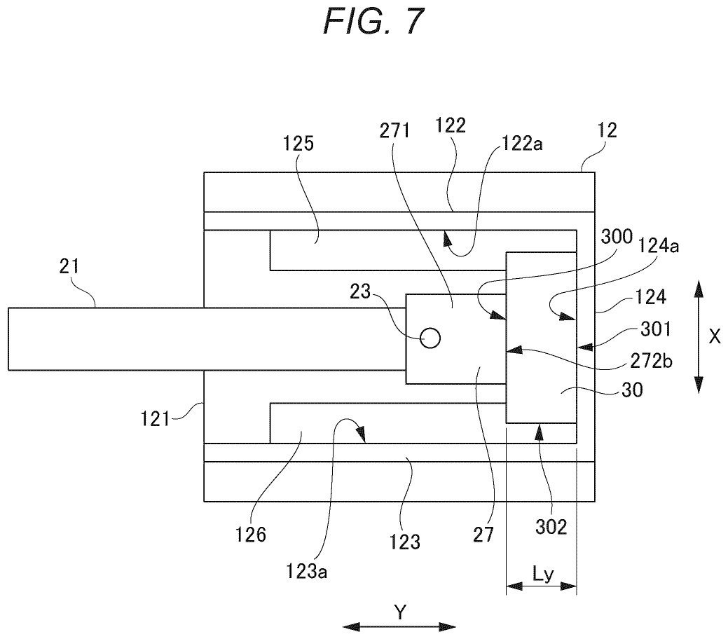

FIG. 5 is a schematic side view illustrating a configuration of the hand portion of the conveyance device. FIG. 6 is a view for explaining an example of setting a length of a pressing member illustrated in FIG. 5. FIG. 7 is a schematic plan view illustrating a state in which the hand portion of the conveyance device is entered into one of the cassettes.

As illustrated in FIG. 5, the hand portion 16 of the conveyance device 13 (see FIG. 1) includes a hand frame 21, a bearing 22, a shaft 23, a vacuum generator 24, a spring 25, a suction pad 26, and the pressing member 27.

A proximal end portion of the hand frame 21 is attached to a distal end portion of the conveyance device 13 constituted by the six-axis robot. The bearing 22 is attached to a distal end portion of the hand frame 21. The shaft 23 is movably supported by the hand frame 21 via the bearing 22. The shaft 23 is disposed so as to extend through the hand frame 21. The vacuum generator 24 is attached to a lower end portion of the shaft 23. The vacuum generator 24 is a device that generates a suction force for holding a sample 30 by vacuum suction. The spring 25 is attached to the shaft 23 at a position between the bearing 22 and the vacuum generator 24. The spring 25 is a member that biases the shaft 23 and the vacuum generator 24 downward in FIG. 5. A part of the shaft 23 is abutted against a stopper (not illustrated) by the biasing force of the spring 25.

The suction pad 26 is attached to a lower end portion of the vacuum generator 24. The suction pad 26 is a rubber pad capable of sucking the sample 30. The suction pad 26 is formed in a cylindrical shape. The suction pad 26 sucks a surface (hereinafter, also referred to as a “sucked surface”) 30b of the sample 30 opposite to a surface 30a of the sample 30 to be measured. The surface 30a of the sample 30 to be measured is arranged in a state of being close to and facing the measurement section 15 when the surface condition of the sample 30 is to be measured by the measurement section 15 of the measuring device 11 illustrated in FIGS. 1 and 2.

The pressing member 27 is capable of pressing the sample stored in the cassette 12 against a reference end portion of the cassette in the depth direction Y. In the present embodiment, as an example, the back plate portion 124 of the cassette 12 corresponds to the reference end portion of the cassette 12 in the depth direction Y. The pressing member 27 is attached to an upper end portion of the shaft 23.

The pressing member 27 includes a first arm portion 271 and a second arm portion 272.

The first arm portion 271 and the second arm portion 272 may be an integral structure or may be separate structures. The first arm portion 271 is fixed to the upper end portion of the shaft 23.

As specific fixing means, for example, screwing, press-fitting, or the like is conceivable. The pressing member 27 is movable integrally with the shaft 23 in the top/bottom direction in FIG. 5. The first arm portion 271 extends in the horizontal direction from the upper end portion of the shaft 23. The second arm portion 272 extends vertically downward from a distal end portion of the first arm portion 271. The second arm portion 272 is disposed in a direction perpendicular to the first arm portion 271.

A lower end portion 272a of the second arm portion 272 is disposed vertically above a suction surface of the suction pad 26. The suction surface of the suction pad 26 is a surface for sucking the sample 30. In the present embodiment, the top/bottom direction is defined with reference to the posture of the hand portion 16 when the sample 30 is taken out from the cassette 12 serving as the pickup source. In the central axis direction of the shaft 23, as illustrated in FIG. 3, a length Lg of a gap between the lower end portion 272a of the second arm portion 272 and the suction surface of the suction pad 26 is smaller than a distance between two support portions 125 adjacent to each other in the height direction Z of the cassette, that is, in one stage.

A length of the pressing member 27 in the height direction Z of the cassette is set to a length of a plurality of stages of the cassette 12. FIG. 6 illustrates, as an example, a case where the length La of the pressing member 27 in the height direction Z of the cassette is set to a length Lb of five stages of the cassette 12. In this case, a sample detector 19 which will be described later can collectively detect the presence or absence of samples in the respective five stages of the cassette 12 using the pressing member 27. The length La of the pressing member 27 can be changed as necessary.

As illustrated in FIGS. 5 and 7, a contact surface 272b is formed on the lower end portion 272a of the second arm portion 272. When the sample 30 is pressed against the back plate portion 124 by the pressing member 27, the contact surface 272b contacts the sample 30. The contact surface 272b is formed in a planar shape such that the pressing member 27 contacts the sample 30 with a flat surface.

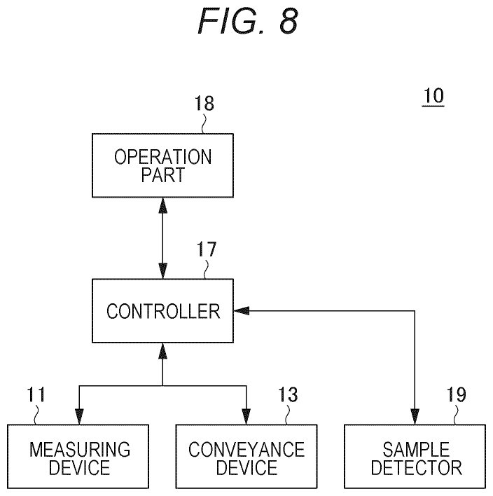

FIG. 8 is a block diagram illustrating a configuration of a control system of the sample measuring apparatus according to the first embodiment of the present invention.

As illustrated in FIG. 8, the sample measuring apparatus 10 includes a controller 17, an operation part 18, and the sample detector 19, in addition to the measuring device 11 and the conveyance device 13 described above. The controller 17 comprehensively controls the operation of each part of the sample measuring apparatus 10. The controller 17 includes, for example, as hardware resources of a computer, a processor such as a central processing unit (CPU) and a storage section including a read only memory (ROM), a random access memory (RAM), and a hard disk drive (HDD). Functions of the controller 17 are implemented by the processor reading a program stored in advance in the ROM into the RAM and executing the program.

The operation part 18 functions as a user interface. Specifically, the operation part 18 displays various information to a user who uses the sample measuring apparatus 10. Further, the operation part 18 receives an input of various kinds of information from the user. The operation part 18 includes, for example, a display part and an input part (not illustrated). In addition, the operation part 18 receives an input for the user to set information (hereinafter, also referred to as “sample information”) regarding a sample stored in each stage of each of the cassettes 12. In this case, the user sets sample information regarding an unmeasured sample for a stage in which the unmeasured sample is stored (set), and does not set sample information for a stage in which an unmeasured sample is not stored and leaves the sample information blank, or sets information indicating that no sample is stored in the stage. The user inputs the sample information by operating the operation part 18.

The sample information includes, for example, the following pieces of information (1) to (6).
(1) The size of the sample
(2) The shape of the sample
(3) The mass of the sample
(4) The material of the sample
(5) Information designating a cassette 12 in which an unmeasured (measurement target) sample is stored and a stage in which the unmeasured sample is stored in the cassette 12
(6) Information designating a cassette 12 in which a measured sample is to be stored and a stage in which the measured sample is to be stored in the cassette 12

Furthermore, the size of the sample includes, for example, the following sizes (a) to (c).
(a) The size of the sample in the width direction X of the cassette
(b) The size of the sample in the depth direction Y of the cassette
(c) The thickness of the sample

The sample information is set for each stage of each of the cassettes 12. The sample information is set by the user operating the operation part 18 before the sample measuring apparatus 10 starts operating. The sample information set by the user via the operation part 18 is stored in, for example, the storage section of the controller 17.

The sample detector 19 can detect the presence or absence of a sample in each stage of each of the cassettes 12.

The sample detector 19 detects the presence or absence of a sample in a predetermined stage of the cassette 12 serving as the pickup source and a predetermined stage of the cassette 12 serving as the placement destination. The predetermined stage of the cassette 12 serving as the pickup source is a stage on the upper side of a stage in which an unmeasured sample is stored in the cassette 12 serving as the pickup source. The stage in which the unmeasured sample is stored is a stage specified by the user via the operation part 18. The predetermined stage of the cassette serving as the placement destination is a stage in which a measured sample is stored and a stage on the upper side of the stage in which the measured sample is stored. The stage in which the measured sample is stored is a stage specified by the user via the operation part 18 as described in (6) above.

The sample detector 19 includes the pressing member 27 illustrated in FIGS. 5 and 6. The pressing member 27 is attached to the hand portion 16 of the conveyance device 13.

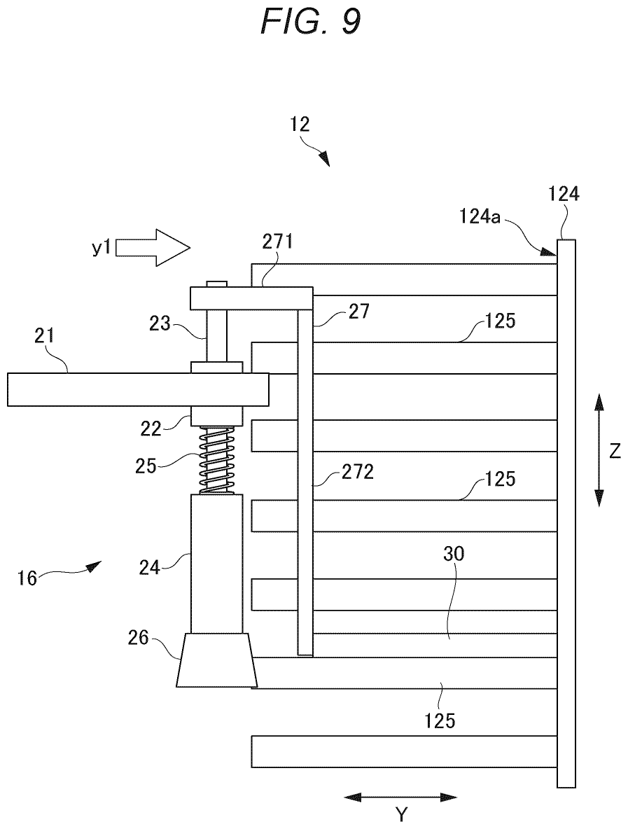

As illustrated in FIG. 9, the sample detector 19 senses whether or not a sample 30 has been pressed against the back plate portion 124 based on a measured value of the six-axis force sensor in a process in which the pressing member 27 is brought close to the back plate portion 124 of the cassette 12 by the horizontal movement of the hand portion 16 in a y1 direction. Then, when sensing that the sample 30 has been pressed against the back plate portion 124, the sample detector 19 determines that the sample 30 is present in a checking range. In other words, when the sample 30 pressed by the pressing member 27 abuts against the back plate portion 124, the sample detector 19 detects that the sample 30 is present in the checking range.

The checking range refers to a range in which the presence or absence of the sample is checked by using the pressing member 27 in the height direction Z of the cassette. For example, when the length La of the pressing member 27 is set to the length Lb (see FIG. 6) corresponding to the five stages of the cassette 12, and the pressing member 27 collectively checks the presence or absence of samples 30 in the five stages, the checking range is a range corresponding to the five stages. In addition, even in a case where the length La of the second arm portion 272 is set to the length Lb corresponding to five stages of the cassette 12, and the pressing member 27 checks the presence or absence of the sample 30 in only one stage, the checking range is a range corresponding to one stage.

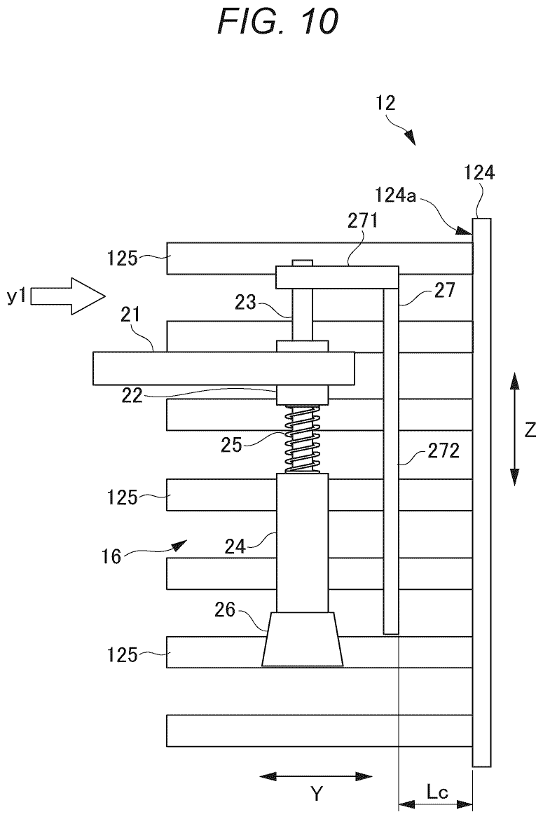

The pressing force of the pressing member 27 for detecting the presence or absence of a sample 30 is set to a magnitude that does not damage the sample 30. Furthermore, as illustrated in FIG. 10, in a process in which the pressing member 27 is brought close to the back plate portion 124 of the cassette 12 by the horizontal movement of the hand portion 16 in the y1 direction, when the sample detector 19 detects that a length Lc from the back plate portion 124 to the pressing member 27 is smaller than the minimum sample size, the sample detector 19 determines that a sample 30 is not present in the checking range. In other words, when the length Lc from the back plate portion 124 to the pressing member 27 is smaller than the minimum sample size, the sample detector 19 detects that a sample 30 is not present in the checking range.

The minimum sample size refers to the minimum sample size in the depth direction Y of the cassette among sample sizes included in sample information set by the user via the operation part 18. Therefore, when a sample 30 is present in the checking range, the sample 30 is pressed against the back plate portion 124 before the length Le from the back plate portion 124 to the pressing member 27 becomes smaller than the minimum sample size.

The operation of the conveyance device 13 for detecting the presence or absence of a sample 30 using the pressing member 27 is controlled by the controller 17. When the presence or absence of a sample 30 is to be detected by using the pressing member 27, the sample detector 19 recognizes the position of the pressing member 27 and the position of each portion of the cassette 12 in the coordinate system of the conveyance device 13. In a case where the sample detector 19 determines that a sample 30 is not present in the above-described checking range, the controller 17 stops the horizontal movement of the hand portion 16 before the pressing member 27 contacts the back plate portion 124.

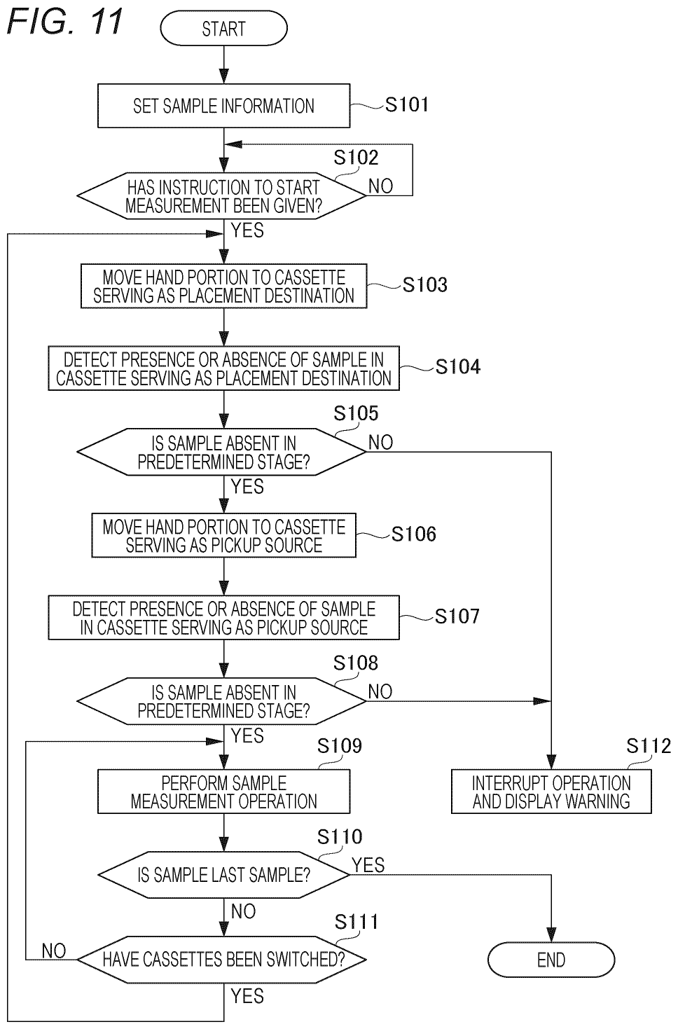

FIG. 11 is a flowchart illustrating an example of a processing procedure for measuring a sample using the sample measuring apparatus according to the first embodiment of the present invention.

First, the user operates the operation part 18 to set the above-described sample information (step S101). The sample information set by the user is stored in the storage section of the controller 17. The sample information includes the information (1) to (6) described above.

Next, the controller 17 repeatedly determines whether or not an instruction to start measurement has been given (step S102). In this case, when the user presses a measurement start button (not illustrated), the controller 17 determines that the instruction to start measurement has been given. The measurement start button is provided, for example, on the operation part 18.

Next, the controller 17 drives the conveyance device 13 to move the hand portion 16 from a home position to the position where the cassette 12 serving as the placement destination is installed (step S103).

The home position is determined in advance. Note that before step S103, the controller 17 may check whether or not the cassette 12 serving as the pickup source and the cassette 12 serving as the placement destination are installed (mounted) at predetermined positions on the base 14. As a specific example, when the color of a sample is automatically measured by using three cassettes 12, the controller 17 checks whether or not the three cassettes 12 are installed at predetermined positions.

Next, the sample detector 19 detects the presence or absence of a sample in a predetermined stage of the cassette 12 serving as the placement destination (step S104). The predetermined stage of the cassette 12 serving as the placement destination is a stage in which the measured sample is stored and a stage on the upper side of the stage in which the measured sample is stored. Hereinafter, specific examples will be described.

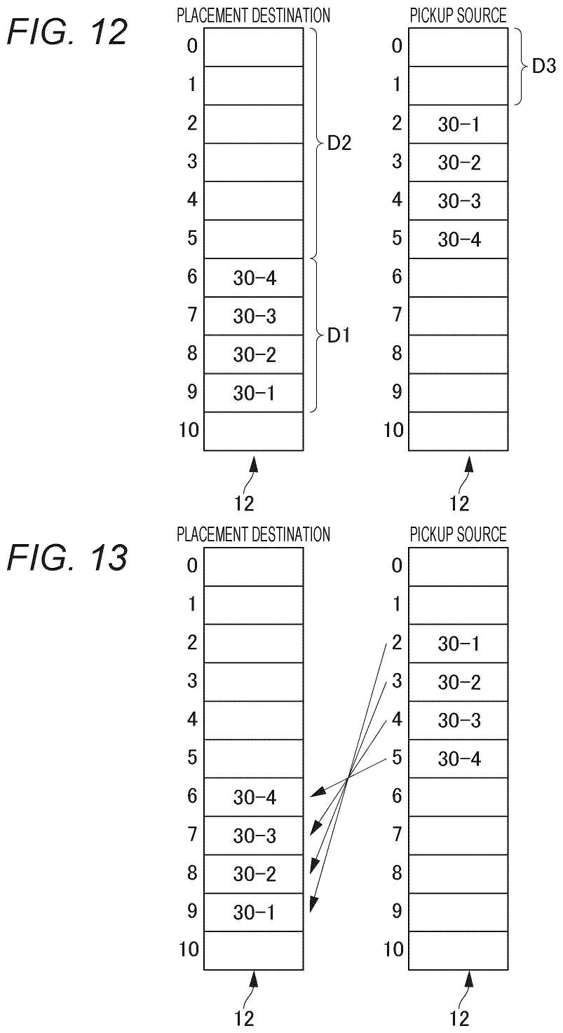

First, for convenience of explanation, an example as illustrated in FIG. 12 is considered. In FIG. 12, the cassette 12 serving as the pickup source and the cassette 12 serving as the placement destination each have a total of 11 stages from the zeroth stage to the tenth stage from the top to the bottom. Further, in the cassette 12 serving as the pickup source, samples 30 (30-1, 30-2, 30-3, and 30-4) are stored in the respective second to fifth stages as set by the user via the operation part 18.

The four samples 30 stored in the cassette 12 serving as the pickup source are stored in the cassette 12 serving as the placement destination in accordance with the content set by the user via the operation part 18. Specifically, as illustrated in FIG. 13, the sample 30-1 stored in the second stage of the cassette 12 serving as the pickup source is measured by the measuring device 11, and then stored in the ninth stage of the cassette 12 serving as the placement destination. The sample 30-2 stored in the third stage of the cassette 12 serving as the pickup source is measured by the measuring device 11 and then stored in the eighth stage of the cassette 12 serving as the placement destination. The sample 30-3 stored in the fourth stage of the cassette 12 serving as the pickup source is measured by the measuring device 11 and then stored in the seventh stage of the cassette 12 serving as the placement destination. The sample 30-4 stored in the fifth stage of the cassette 12 serving as the pickup source is measured by the measuring device 11 and then stored in the sixth stage of the cassette 12 serving as the placement destination.

In such a case, as illustrated in FIG. 12, the sample detector 19 specifies, as a predetermined stage D1, the sixth to ninth stages in which the measured samples are stored in the cassette 12 serving as the placement destination and specifies, as a predetermined stage D2, the zeroth to fifth stages on the upper side of the stages in which the measured samples are stored in the cassette 12 serving as the placement destination. Then, the sample detector 19 detects the presence or absence of a sample in the predetermined stages D1 and D2 of the cassette 12 serving as the placement destination. To be specific, the sample detector 19 detects whether or not the predetermined stages D1 and D2 of the cassette 12 serving as the placement destination are in a state of storing no sample, that is, empty.

A case where a sample is present in a predetermined stage of the cassette 12 serving as the placement destination is, for example, a case where the user forgets to take the sample from the predetermined stage in preparation work of installing the cassette 12 serving as the placement destination on the base 14. In this case, when a sample measurement operation is started with the sample remaining in the predetermined stage, and the sample 30-1 held by the hand portion 16 of the conveyance device 13 is to be stored in the cassette 12 serving as the placement destination, the hand portion 16 or the like of the conveyance device 13 may collide with the sample remaining in the predetermined stage, and the sample may be damaged.

Therefore, in the present embodiment, before the start of the sample measurement operation in step S109, the sample detector 19 checks whether or not a sample 30 remains in the predetermined stage of the cassette 12 serving as the placement destination. The sample measurement operation includes an operation of taking out a sample 30 from the cassette 12 serving as the pickup source, an operation of measuring the taken-out sample 30 by the measuring device 11, and an operation of storing the sample 30 measured by the measuring device 11 into the cassette 12 serving as the placement destination. For this reason, the processing in step S104 is performed before the measured sample 30 starts to be stored in the cassette 12 serving as the placement destination.

When the sample detector 19 detects the presence or absence of a sample in the predetermined stage of the cassette 12 serving as the placement destination, the controller 17 controls the operation of the conveyance device 13 as follows.

First, as illustrated in FIG. 6, the controller 17 arranges the pressing member 27 in front of the cassette 12 serving as the placement destination. Furthermore, the controller 17 arranges the pressing member 27 in accordance with the height position of the predetermined stage of the cassette 12 serving as the placement destination. Next, the controller 17 horizontally moves the hand portion 16 in the y1 direction (see FIG. 9) from the front side to the back side of the cassette 12 serving as the placement destination.

Accordingly, the pressing member 27 gradually approaches the back plate portion 124 of the cassette 12 serving as the placement destination while moving together with the hand portion 16.

When a sample 30 stored in the predetermined stage is pressed against the back plate portion 124 by the pressing member 27 during the horizontal movement of the hand portion 16 described above, the sample detector 19 detects that the sample 30 is present in the predetermined stage. Furthermore, when the length from the back plate portion 124 to the pressing member 27 becomes smaller than the minimum sample size during the horizontal movement of the hand portion 16, the sample detector 19 detects that a sample 30 is not present in the predetermined stage. The result of the detection by the sample detector 19 is transmitted from the sample detector 19 to the controller 17.

Next, the controller 17 determines (checks) whether or not a sample 30 is absent in the predetermined stage of the cassette 12 serving as the placement destination based on the result of the detection by the sample detector 19 in step S104 (step S105). Next, when the controller 17 confirms that the sample 30 is absent in the predetermined stage of the cassette 12 serving as the placement destination, that is, when the controller 17 makes an affirmative determination in step S105, the controller 17 proceeds to step S106. In addition, when the controller 17 confirms that the sample 30 is present in the predetermined stage of the cassette 12 serving as the placement destination, that is, when the controller 17 makes a negative determination in step S105, the controller 17 proceeds to step S112.

In step S106, the controller 17 drives the conveyance device 13 to move the hand portion 16 from the position where the cassette 12 serving as the placement destination is installed to the position where the cassette 12 serving as the pickup source is installed. Next, the sample detector 19 detects the presence or absence of a sample in the predetermined stage of the cassette 12 serving as the pickup source (step S107). The predetermined stage of the cassette 12 serving as the pickup source is a stage on the upper side of a stage in which an unmeasured sample is stored in the cassette 12 serving as the pickup source. For example, in FIG. 12, as set by the user via the operation part 18, the unmeasured samples 30 (30-1, 30-2, 30-3, and 30-4) are stored in the respective second to fifth stages of the cassette 12 serving as the pickup source. In this case, the sample detector 19 specifies, as a predetermined stage D3, the zeroth stage and the first stage which are stages on the upper side of the stage in which the unmeasured sample is stored in the cassette 12 serving as a pickup source. Then, the sample detector 19 detects the presence or absence of a sample in the predetermined stage D3 of the cassette 12 serving as the pickup source. To be more specific, the sample detector 19 detects whether or not the predetermined stage D3 of the cassette 12 serving as the pickup source is in a state of storing no sample, that is, empty.

The case where the sample is present in the predetermined stage of the cassette 12 serving as the pickup source is, for example, a case where the user mistakenly sets the sample 30 in the predetermined stage in the preparatory work for installing the cassette 12 serving as the pickup source on the base 14. In this case, when the sample measurement operation is started with the sample 30 set in the predetermined stage, and the conveyance device 13 takes out the first sample 30 (sample 30-1 in the example of FIG. 12) from the cassette 12 serving as the pickup source, the hand portion 16 or the like of the conveyance device 13 may collide with the sample mistakenly set in the predetermined stage, and the sample may be damaged.

For this reason, in the present embodiment, before the start of the sample measurement operation in step S109, the sample detector 19 checks whether or not a sample 30 is mistakenly set in the predetermined stage of the cassette 12 serving as the pickup source. As described above, the sample measurement operation includes the operation of taking out a sample 30 from the cassette 12 serving as the pickup source, the operation of measuring the taken-out sample 30 by the measuring device 11, and the operation of storing the sample 30 measured by the measuring device 11 into the cassette 12 serving as the placement destination. Therefore, the processing in step S107 described above is performed before the start of the operation of taking out the sample 30 from the cassette 12 serving as the pickup source.

Note that an operation for the sample detector 19 to detect the presence or absence of a sample in the predetermined stage of the cassette 12 serving as the pickup source is basically the same as the above-described operation for the sample detector 19 to detect the presence or absence of a sample in the predetermined stage of the cassette 12 serving as the placement destination, and thus description thereof will be omitted.

Next, the controller 17 determines (checks) whether or not a sample 30 is absent in the predetermined stage of the cassette 12 serving as the pickup source based on a result of the detection by the sample detector 19 in step S107 (step S108). Then, when the controller 17 confirms that the sample 30 is absent in the predetermined stage of the cassette 12 serving as the pickup source, that is, when the controller 17 makes an affirmative determination in step S108, the controller 17 proceeds to step S109. In addition, when the controller 17 confirms that the sample 30 is present in the predetermined stage of the cassette 12 serving as the pickup source, that is, when the controller 17 makes a negative determination in step S108, the controller 17 proceeds to step S112.

In step S112, the controller 17 interrupts (stops) the sample measurement operation by the measuring device 11 and the conveyance device 13, and displays a warning. The displayed content of the warning varies depending on whether the controller 17 proceeds from step S105 to step S112 or proceeds from step S108 to step S112. For example, when the controller 17 proceeds from step S105 to step S112, the controller 17 displays that the sample is left in the cassette 12 serving as the placement destination. In addition, when the controller 17 proceeds from step S108 to step S112, the controller 17 displays that the sample is mistakenly set in the cassette 12 serving as the pickup source. The displayed content of the warning can be changed in various ways. In addition, the flowchart of FIG. 11 illustrates an example in which the processing in steps S103 to S105 is performed after the processing in steps S106 to S108 is performed, but the processing in steps S106 to S108 may be performed after the processing in steps S103 to S105 is performed.

On the other hand, in step S109, the controller 17 causes the measuring device 11 and the conveyance device 13 to perform the sample measurement operation. As described above, the sample measurement operation includes an operation of taking out a sample 30 from the cassette 12 serving as the pickup source, an operation of measuring the taken-out sample 30 by the measuring device 11, and an operation of storing the sample 30 measured by the measuring device 11 into the cassette 12 serving as the placement destination. More specifically, the controller 17 controls the operation of the conveyance device 13 to suck and pick up the sample 30 stored in a takeout target stage of the cassette 12 with the suction pad 26 of the hand portion 16, and then take out the sample 30 from the takeout target stage of the cassette 12. Next, the controller 17 moves the sample 30 sucked by the suction pad 26 to the measurement position of the measuring device 11 by controlling the operation of the conveyance device 13. Next, the controller 17 measures the sample 30 for a predetermined item by controlling the operation of the measuring device 11. Next, the controller 17 controls the operation of the conveyance device 13 to covey the sample 30 to the cassette 12 serving as the placement destination while sucking the measured sample 30 by the suction pad 26. Next, the controller 17 places the sample 30 in a storage target stage of the cassette 12 serving as the placement destination by controlling the operation of the conveyance device 13. Thus, the measured sample 30 is stored in the cassette 12 serving as the placement destination.

Next, the controller 17 determines whether or not the sample 30 taken out as a measurement target in step S109 is the last sample (step S110). When the controller 17 makes a negative determination in step S110, the controller 17 proceeds to step S111. In step S111, the controller 17 determines whether or not the cassettes 12 have been switched to each other. The switching of the cassettes 12 refers to switching between the cassette 12 serving as the pickup source and the cassette 12 serving as the placement destination. When the controller 17 makes a negative determination in step S111, the controller 17 returns to step S109. When the controller 17 makes a positive determination in step S111, the controller 17 returns to step S103. When the controller 17 returns from step S111 to step S103, the processing from step S103 to step S108 is performed on the cassettes 12 after the switching. In addition, when the controller 17 makes an affirmative determination in step S110, the controller 17 ends the series of processing.

Note that although FIG. 11 illustrates the case where the cassettes 12 are switched to each other as an example of the case where it is necessary to detect the presence or absence of a sample by the sample detector 19, the present invention is not limited to this example. For example, when it is necessary to detect the presence or absence of a sample by the sample detector 19, groups of samples taken out from the cassette 12 serving as the pickup source may be switched. When the user sets the sample information via the operation part 18, the groups of the samples are classified according to, for example, the types of the samples. The types of the samples are classified according to, for example, a difference in material, size, or the like between the samples.

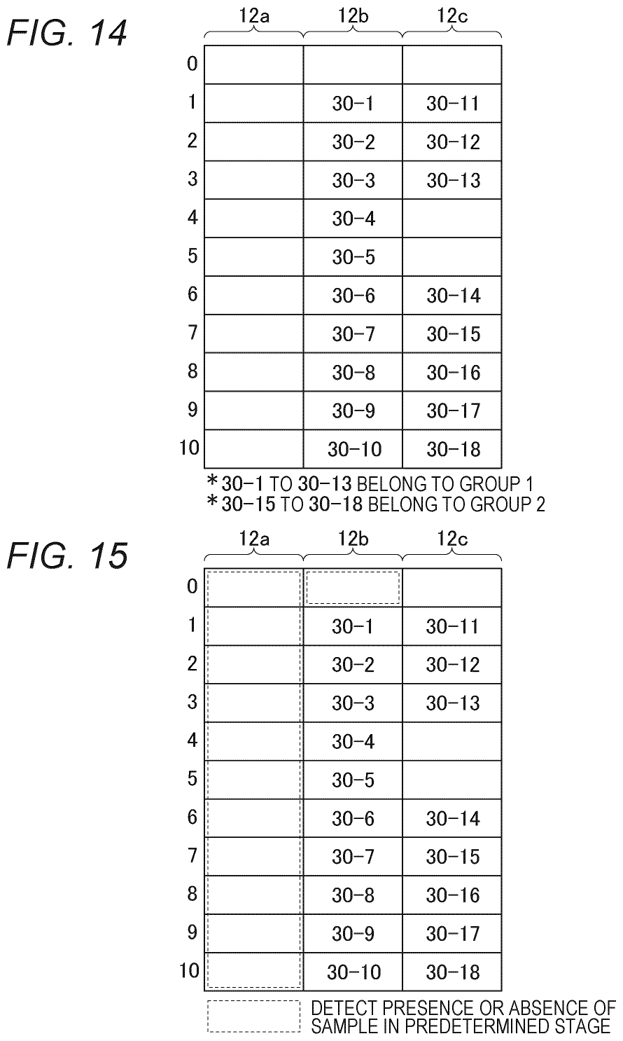

FIGS. 14 to 20 are schematic views for explaining an example in which samples are measured by the sample measuring apparatus using three cassettes.

First, as a premise of the description, as illustrated in FIG. 14, each of the three cassettes 12a, 12b, and 12c has a total of 11 stages from the zeroth stage to the tenth stage from the top to the bottom. The cassette 12a is an empty cassette in which no sample is stored. A total of ten samples 30 (30-1 to 30-10) are stored in the first to tenth stages of the cassette 12b. A total of eight samples 30 (30-11 to 30-18) are stored in the first to third stages and the sixth to tenth stages of the cassette 12c. The samples 30 (30-11 to 30-13) stored in the first to third stages of the cassette 12c and the samples 30 (30-14 to 30-18) stored in the sixth to tenth stages of the cassette 12c are samples belonging to different groups.

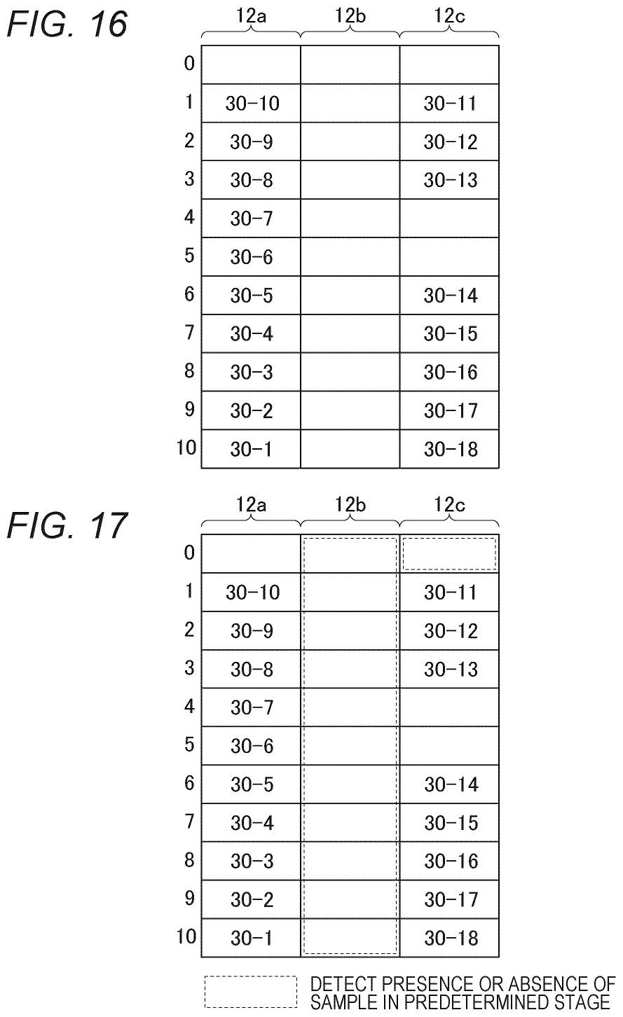

Under such a premise, the sample detector 19 first detects the presence or absence of a sample by setting the cassette 12a as a cassette serving as a placement destination and the cassette 12b as a cassette serving as a pickup source. To be more specific, as illustrated in FIG. 15, the sample detector 19 sets the zeroth to tenth stages of the cassette 12a serving as a placement destination as a predetermined stage, and detects the presence or absence of a sample in the predetermined stage. Further, the sample detector 19 sets the zeroth stage of the cassette 12b serving as the pickup source as a predetermined stage, and detects the presence or absence of a sample in the predetermined stage. Next, when the sample detector 19 detects that a sample is not present in the predetermined stage of the cassette 12a serving as the placement destination and that a sample is not present in the predetermined stage of the cassette 12b serving as the pickup source, the sample measurement operation is performed by the measuring device 11 and the conveyance device 13 under control by the controller 17. In the sample measurement operation, the ten samples 30 (30-1 to 30-10) stored in the cassette 12b are taken out from the cassette 12b in order from the top stage and measured by the measuring device 11. In addition, as illustrated in FIG. 16, the measured samples 30 (30-1 to 30-10) are stored in the cassette 12a in order from the bottom stage (the tenth stage in the illustrated example) of the cassette 12a. At this point of time, the cassette 12b is empty.

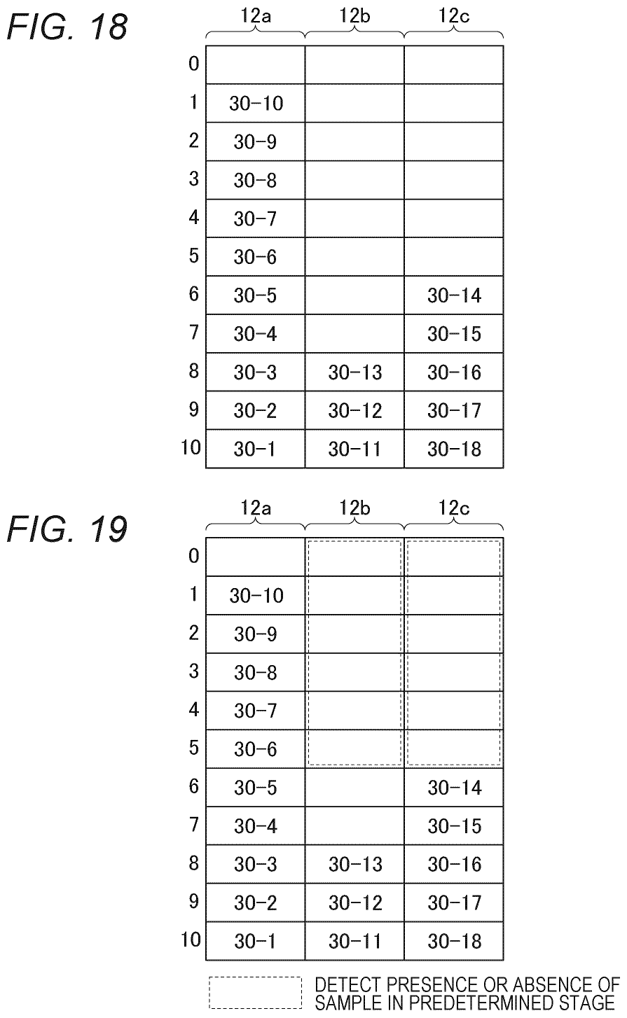

Subsequently, the sample detector 19 detects the presence or absence of a sample by setting the cassette 12b as a cassette serving as a placement destination and the cassette 12c as a cassette serving as a pickup source. In other words, the sample detector 19 detects the presence or absence of a sample when the cassettes 12 are switched. To be more specific, as illustrated in FIG. 17, the sample detector 19 sets the zeroth to tenth stages of the cassette 12b serving as the placement destination as a predetermined stage, and detects the presence or absence of a sample in the predetermined stage. In addition, the sample detector 19 sets the zeroth stage of the cassette 12c serving as the pickup source as a predetermined stage, and detects the presence or absence of a sample in the predetermined stage. Next, when the sample detector 19 detects that a sample is not present in the predetermined stage of the cassette 12b serving as the placement destination and that a sample is not present in the predetermined stage of the cassette 12c serving as the pickup source, the sample measurement operation is performed by the measuring device 11 and the conveyance device 13 under control by the controller 17. In the sample measurement operation, among the eight samples 30 stored in the cassette 12c, the samples 30-11 to 30-13 stored in the first to third stages are taken out in order from the upper stage and measured by the measuring device 11. As illustrated in FIG. 18, the measured samples 30-11 to 30-13 are stored in the cassette 12b in order from the lower stage (the tenth stage in the illustrated example) of the cassette 12b.

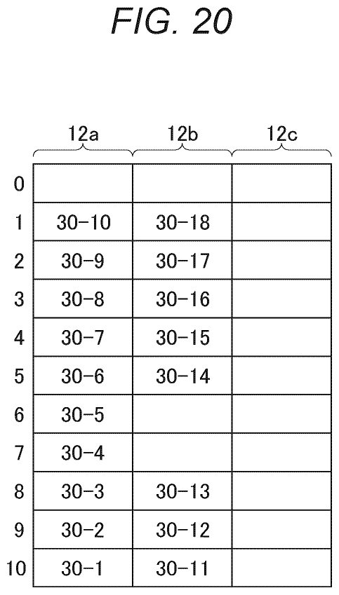

Subsequently, the sample detector 19 detects the presence or absence of a sample at the timing when the group of the samples 30 is switched. In other words, the sample detector 19 detects the presence or absence of a sample when the group of the samples 30 is switched. To be more specific, as illustrated in FIG. 19, the sample detector 19 sets the zeroth to fifth stages of the cassette 12b serving as the placement destination as a predetermined stage, and detects the presence or absence of a sample in the predetermined stage. The sample detector 19 sets the zeroth to fifth stages of the cassette 12c of the pickup source as a predetermined stage, and detects the presence or absence of a sample in the predetermined stage. Next, when the sample detector 19 detects that a sample is not present in the predetermined stage of the cassette 12b serving as the placement destination and that a sample is not present in the predetermined stage of the cassette 12c serving as the pickup source, the sample measurement operation is performed by the measuring device 11 and the conveyance device 13 under control by the controller 17. In this sample measurement operation, the samples 30-14 to 30-18 remaining in the cassette 12c are taken out from the cassette 12c in order from the upper stage and measured by the measuring device 11. As illustrated in FIG. 20, the measured samples 30-14 to 30-18 are stored in the cassette 12b in order from the fifth stage to the first stage of the cassette 12b.

As described above, the sample measuring apparatus 10 according to the first embodiment of the present invention includes the sample detector 19 and the controller 17 in addition to the measuring device 11 and the conveyance device 13. The sample detector 19 can detect the presence or absence of a sample in each stage of each of the cassettes 12. The controller 17 controls the measuring device 11 and the conveyance device 13 based on a result of the detection by the sample detector 19. As a result, the sample measuring apparatus 10 can perform the sample measurement operation in a state in which a sample is not present in the predetermined stage of the cassette 12 serving as the placement destination and in the predetermined stage of the cassette 12 serving as the pickup source. Therefore, even when the user mistakenly sets a sample in the predetermined stage of the cassette 12 serving as the pickup source, it is possible to avoid collision of the hand portion 16 or the like of the conveyance device 13 with the mistakenly set sample. Furthermore, even in a case where the user has forgotten to take a sample from the predetermined stage of the cassette 12 serving as the placement destination, it is possible to avoid collision of the hand portion 16 or the like of the conveyance device 13 with the sample that the user has forgotten to take. Therefore, according to the sample measuring apparatus 10, it is possible to prevent the sample from being damaged due to a user's mistake.

### Second Embodiment

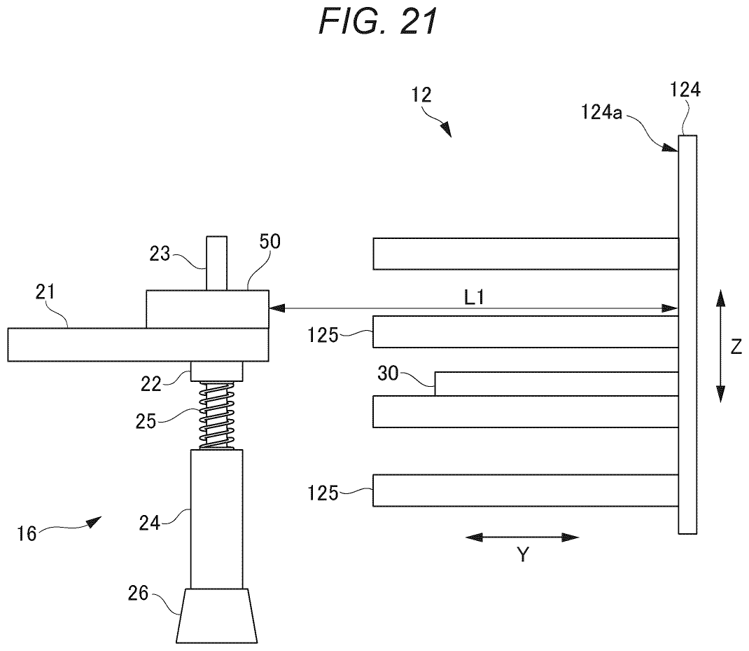

A sample measuring apparatus according to a second embodiment of the present invention is characterized by a configuration of a sample detector 19. The sample detector 19 according to the second embodiment includes a distance measuring sensor 50 illustrated in FIG. 21. The distance measuring sensor 50 is attached to the hand portion 16. Specifically, the distance measuring sensor 50 is attached to an upper surface of the hand frame 21. The distance measuring sensor 50 is capable of measuring a distance from the distance measuring sensor 50 to an object in each stage of each of the cassettes 12 in the depth direction X of the cassette 12. The distance measuring sensor 50 is disposed in front of the cassette 12 in a case of measuring a distance to an object. The object in a case where the distance measuring sensor 50 measures the distance differs depending on whether or not a sample 30 is present in a stage to be measured.

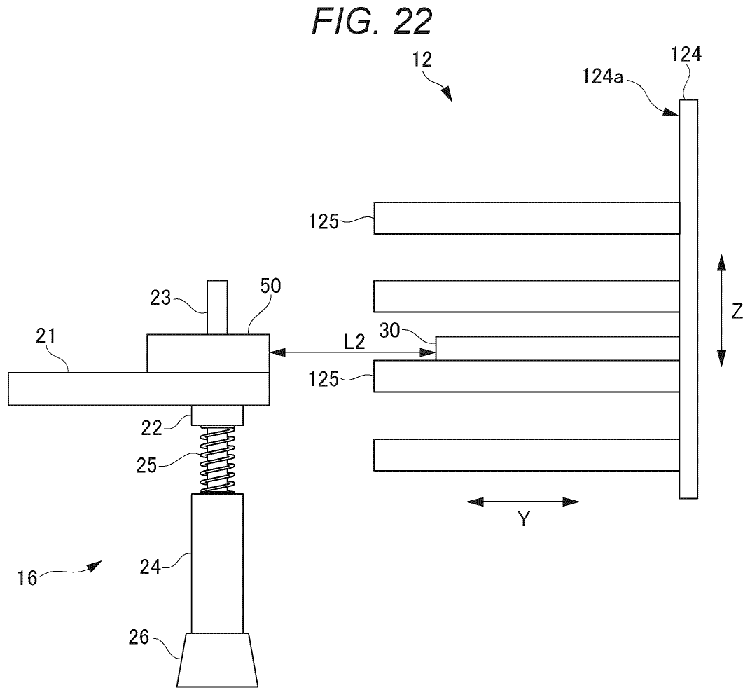

To be more specific, as illustrated in FIG. 21, when a sample 30 is not present in a stage facing the distance measuring sensor 50 in the depth direction Y of the cassette 12, the distance measuring sensor 50 measures the distance L1 from the distance measuring sensor 50 to the back plate portion 124 as the object. Further, as illustrated in FIG. 22, when the sample 30 is present in a stage facing the distance measuring sensor 50 in the depth direction Y of the cassette 12, the distance measuring sensor 50 measures the distance L2 from the distance measuring sensor 50 to the sample 30 as the object.

As described above, the distance measured by the distance measuring sensor 50 greatly differs between the case where the sample 30 is present in the stage to be measured and the case where the sample 30 is not present in the stage to be measured. Therefore, the sample detector 19 compares the distance measured by the distance measuring sensor 50 with a preset threshold, and determines whether or not the sample 30 is present in the stage to be measured based on the result of the comparison.

The threshold for determining the presence or absence of the sample 30 is set to a value smaller than the measured value (L1) obtained when the distance measuring sensor 50 uses the back plate portion 124 as the object. In addition, the threshold is set to a value larger than a measured value obtained when the distance measuring sensor 50 uses a sample 30 having the minimum sample size as an object. Thus, when the distance measured by the distance measuring sensor 50 is larger than the threshold, the sample detector 19 can determine that the sample 30 is not present in the stage to be measured. In addition, when the distance measured by the distance measuring sensor 50 is equal to or smaller than the threshold, the sample detector 19 can determine that the sample 30 is present in the stage to be measured. When the presence or absence of a sample is detected in a predetermined stage of the cassette 12, the position of the distance measuring sensor 50 is adjusted in accordance with the height position of the predetermined stage.

In the case where the sample detector 19 includes the distance measuring sensor 50, the measurement range of the distance measuring sensor 50 in the height direction Z of the cassette 12 is preferably larger than the thickness of the sample 30. Thus, even when a sample 30 with deformation such as warping or bending is stored in the stage to be measured, it is possible to reliably detect the presence or absence of the sample 30.

### Third Embodiment

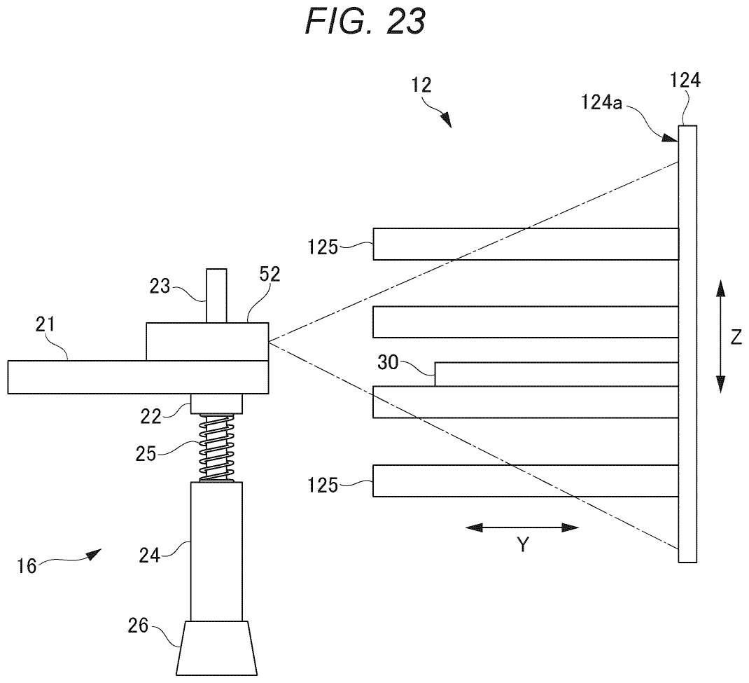

A sample measuring apparatus according to a third embodiment of the present invention is characterized by a configuration of a sample detector 19. The sample detector 19 according to the third embodiment includes an imager 52 illustrated in FIG. 23.

The imager 52 is attached to the hand portion 16. Specifically, the imager 52 is attached to the upper surface of the hand frame 21. The imager 52 captures an image of the inside of each of the cassettes 12 from the front side of the cassette 12. An imaging range of the imager 52 in the height direction Z of the cassette 12 is set to a length corresponding to a plurality of stages of the cassette 12, as illustrated by a one-dot chain line in FIG. 23. Thus, the presence or absence of samples 30 in the respective stages of the cassette 12 can be collectively detected for the plurality of stages by using the imager 52.

When a sample 30 does not appear in an image captured by the imager 52, the sample detector 19 determines that a sample 30 is not present in the imaging range. Furthermore, when a sample 30 is included in the image captured by the imager 52, the sample detector 19 determines that the sample 30 is present in the imaging range. When the presence or absence of a sample in a predetermined stage of the cassette 12 is to be detected, the position of the imager 52 is adjusted in accordance with the height position of the predetermined stage.

### Fourth Embodiment

A sample measuring apparatus according to a fourth embodiment of the present invention is characterized by a configuration of a sample detector 19. The sample detector 19 includes sample detection sensors provided in the respective stages of each of the cassettes 12. The sample detection sensors are provided in all the stages of the cassettes 12. Each of the sample detection sensors is a contact sensor or a non-contact sensor.

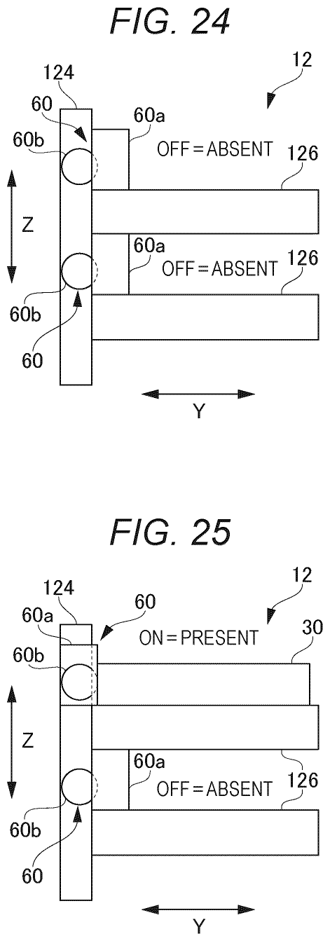

FIGS. 24 and 25 are schematic side views illustrating an example in which each of the sample detection sensors is a contact-type sensor.

As illustrated in FIGS. 24 and 25, the sample detection sensors 60 are provided for the respective support portions 125 and 126 (only the support portions 126 are illustrated in FIGS. 24 and 25) forming the stages of each of the cassettes 12. Each of the sample detection sensors 60 has a contact 60a and a sensor body portion 60b. The contact 60a is displaced from a first position to a second position by coming into contact with a sample 30 which is a detection object. The first position is a position where the sensor body portion 60b is in an off state. The second position is a position where the sensor body portion 60b is in an on state.

As illustrated in FIG. 24, when a sample 30 is not stored in each stage of the cassette 12, the sensor body portion 60b of each sample detection sensor 60 is in an off state. Further, as illustrated in FIG. 25, when the sample 30 is stored in any stage of the cassette 12, the sensor main body portion 60b of the sample detection sensor 60 provided in the stage in which the sample 30 is stored is in an on state, and the sensor body portion 60b of the sample detection sensor 60 provided in a stage in which a sample 30 is not stored is in an off state. Thus, the sample detector 19 can detect the presence or absence of a sample 30 in each stage of the cassette 12 based on the on or off state of each of the sample detection sensors 60.

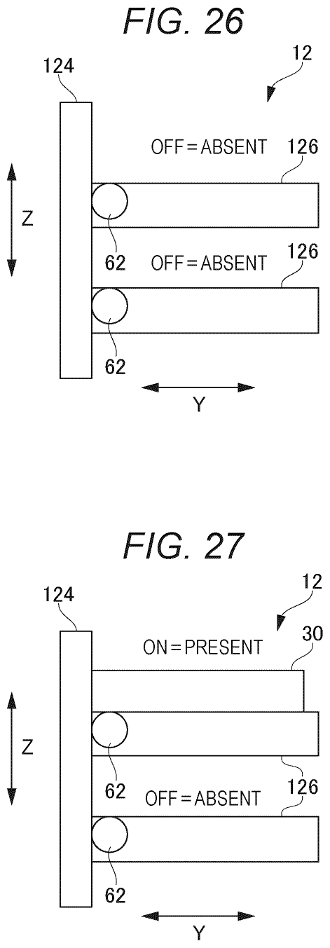

FIGS. 26 and 27 are schematic side views illustrating an example in which each of the sample detection sensors is a non-contact sensor.

As illustrated in FIGS. 26 and 27, the sample detection sensors 62 are provided for the respective support portions 125 and 126 (only the support portion 126 is illustrated in FIGS. 26 and 27) forming the stages of each of the cassettes 12. Each of the sample detection sensors 62 includes, for example, a photoelectric sensor or a proximity sensor. The sample detection sensors 62 are, for example, embedded in the respective support portions 126.

As illustrated in FIG. 26, when a sample 30 is not stored in each stage of the cassette 12, each of the sample detection sensors 62 is in an off state. Further, as illustrated in FIG. 27, when a sample 30 is stored in any stage of the cassette 12, the sample detection sensor 62 provided in the stage in which the sample 30 is stored is in an on state, and the sample detection sensor 62 provided in a stage in which a sample 30 is not stored is in an off state. Thus, the sample detector 19 can detect the presence or absence of a sample 30 in each stage of the cassette 12 based on the on or off state of each of the sample detection sensors 62.

However, the technical scope of the present invention is not limited to the above-described embodiments. The technical scope of the present invention also includes embodiments to which various modifications and improvements are added within a range in which specific effects obtained by the constituent requirements of the invention and combinations thereof can be derived.

For example, in the first embodiment described above, the sample detector 19 is configured to detect the presence or absence of a sample 30 in the predetermined stage of the cassette 12 serving as the pickup source and the predetermined stage of the cassette 12 serving as the placement destination, but the present invention is not limited thereto. For example, the sample detector 19 may be configured to detect the presence or absence of a sample 30 only in the predetermined stage of the cassette 12 serving as the pickup source. Further, the sample detector 19 may be configured to detect the presence or absence of a sample 30 only in the predetermined stage of the cassette 12 serving as the placement destination.

Further, in the first embodiment described above, regarding the cassette 12 serving as the pickup source, the stage on the upper side of the stage in which the unmeasured sample 30 is stored is set as the “predetermined stage”, but the present invention is not limited thereto. For example, regarding the cassette 12 serving as the pickup source, not only the stage on the upper side of the stage in which the unmeasured sample 30 is stored, but also a stage on the lower side of the stage in which the unmeasured sample 30 is stored may be included in the “predetermined stage”.

Furthermore, in the first embodiment described above, regarding the cassette 12 serving as the placement destination, the stage in which the measured sample 30 is stored and the stage on the upper side of the stage in which the measured sample 30 is stored are the “predetermined stages”, but the present invention is not limited thereto. For example, regarding the cassette 12 serving as the placement destination, the “predetermined stage” may include not only the stage in which the measured sample 30 is stored and the stage on the upper side of the stage in which the measured sample 30 is stored but also a stage on the lower side of the stage in which the measured sample 30 is stored.

### Fifth Embodiment

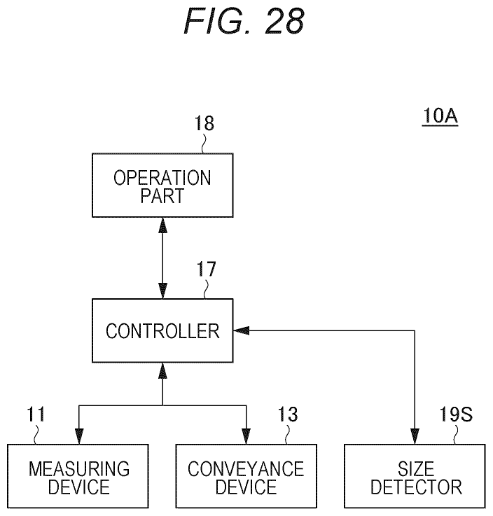

FIG. 28 is a block diagram illustrating a configuration of a control system of a sample measuring apparatus according to a fifth embodiment of the present invention.

As illustrated in FIG. 28, the sample measuring apparatus 10A according to the present embodiment includes a size detector 19S instead of the sample detector 19 of the sample measuring apparatus 10 according to the first embodiment illustrated in FIG. 8.

Note that regarding the setting of sample information via the operation part 18, in the first embodiment, the user sets information regarding an unmeasured sample for a stage in which the unmeasured sample is stored (set), and leaves information blank without setting sample information for a stage in which an unmeasured sample is not stored, or sets information indicating that no sample is stored in the stage. In the present embodiment, the setting of the sample information via the operation part 18 is not limited to the configuration for setting the information on whether or not an unmeasured sample is stored in each stage of each of the cassettes.

The first embodiment exemplifies that the sample information includes (5) information designating a cassette 12 in which an unmeasured (measurement target) sample is stored and a stage in which the unmeasured sample is stored in the cassette 12, and (6) information designating a cassette 12 in which a measured sample is to be stored and a stage in which the measured sample is to be stored in the cassette 12.

In the present embodiment, the sample information may include, instead of the information of (5) and (6), (7) information designating a cassette 12 in which an unmeasured (measurement target) sample is stored, and (8) information designating a cassette 12 in which a measured sample is to be stored.

The size detector 19S detects the sizes of the samples stored in the respective stages of each of the cassettes 12 illustrated in FIG. 3. The size detector 19S detects the size of each sample in the depth direction of the cassette 12 by actual measurement. The size detector 19S includes the pressing member 27 illustrated in FIG. 5. The pressing member 27 is attached to the hand portion 16 of the conveyance device 13. As illustrated in FIG. 7, the size detector 19S detects the size Ly of the sample 30 in the depth direction Y of the cassette 12 by pressing the sample 30 against the back plate portion 124 of the cassette 12 with the pressing member 27. In this case, the operation of the conveyance device 13 for detecting the size of the sample 30 is controlled by the controller 17. In addition, the size detector 19S recognizes the position of the pressing member 27 and the position of each portion of the cassette 12 in the coordinate system of the conveyance device 13. Furthermore, when the sample 30 is pushed to the back side of the cassette 12 by the pressing member 27, the size detector 19S determines, based on a measured value of the above-described six-axis force sensor, whether or not the sample 30 has been pressed against the back plate portion 124.

Other configurations of the sample measuring apparatus 10A according to the present embodiment are the same as those of the sample measuring apparatus 10 according to the first embodiment illustrated in FIG. 8, and thus the description thereof will be omitted.

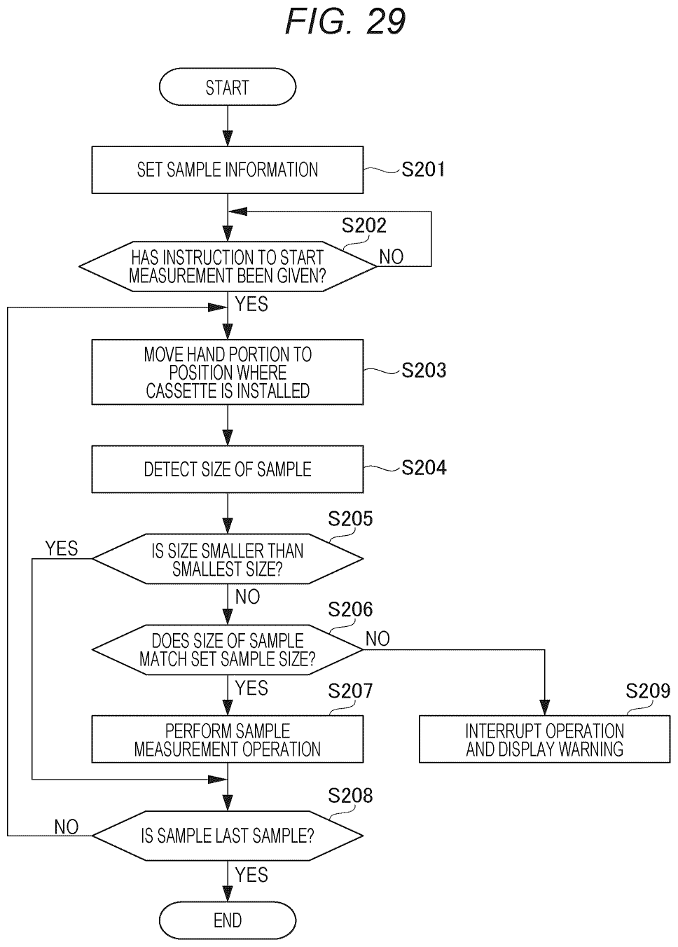

FIG. 29 is a flowchart illustrating an example of a processing procedure for measuring a sample using the sample measuring apparatus 10A according to the fifth embodiment of the present invention.

First, the user operates the operation part 18 to set the above-described sample information (step S201). The sample information set by the user is stored in the storage section of the controller 17. The sample information includes the above-described information (1) to (4) and (7) to (8).

Next, the controller 17 repeatedly determines whether or not an instruction to start measurement has been given (step S202). In this case, when the user presses a measurement start button (not illustrated), the controller 17 determines that the instruction to start measurement has been given. The measurement start button is provided, for example, on the operation part 18.

Next, the controller 17 drives the conveyance device 13 to move the hand portion 16 from the home position to the position where the cassette 12 serving as the pickup source is installed (step S203). The home position is determined in advance. The cassette 12 serving as the pickup source is a cassette in which an unmeasured sample is stored.

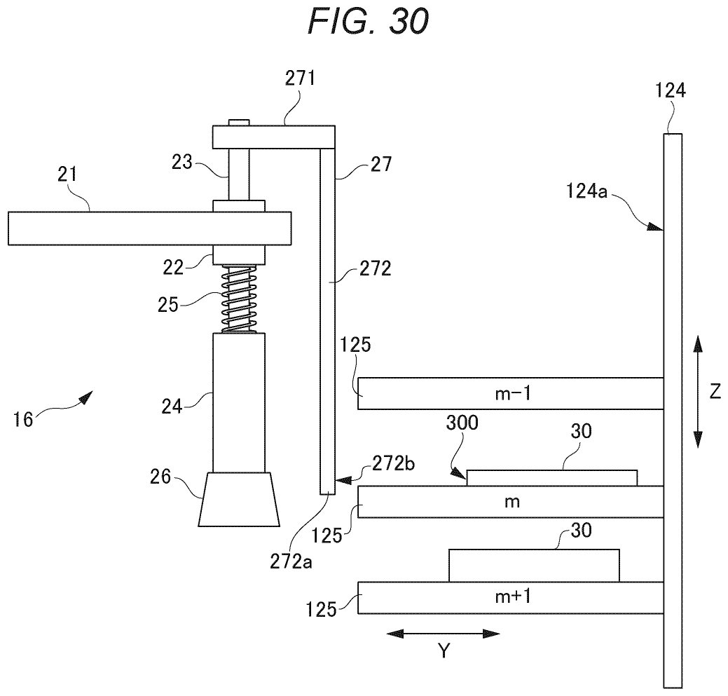

Here, as illustrated in FIG. 30, for example, a case where a sample is taken out from the m-th stage counted from the top of the cassette 12 serving as the pickup source is considered. In this case, as illustrated in FIG. 30, the controller 17 controls the conveyance device 13 such that the lower end portion 272a of the pressing member 27 is located at a position slightly lower than the height positions of the upper surfaces of the pair of support portions 125 and 126 forming the m-th stage. Thus, as illustrated in FIG. 30, when the sample 30 is stored in the m-th stage, a side surface 300 of the sample 30 and the contact surface 272b of the pressing member 27 are arranged to face each other in the depth direction Y of the cassette. The end surface 300 of the sample 30 is arranged facing the front side of the cassette 12.

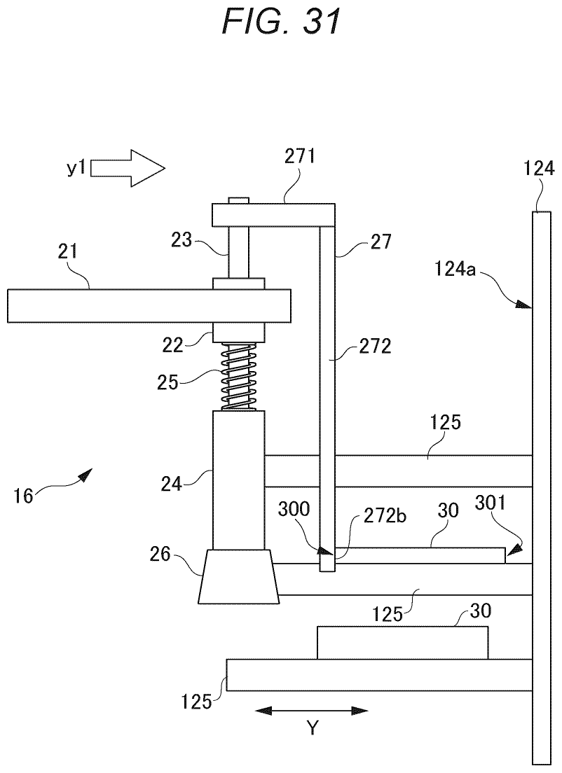

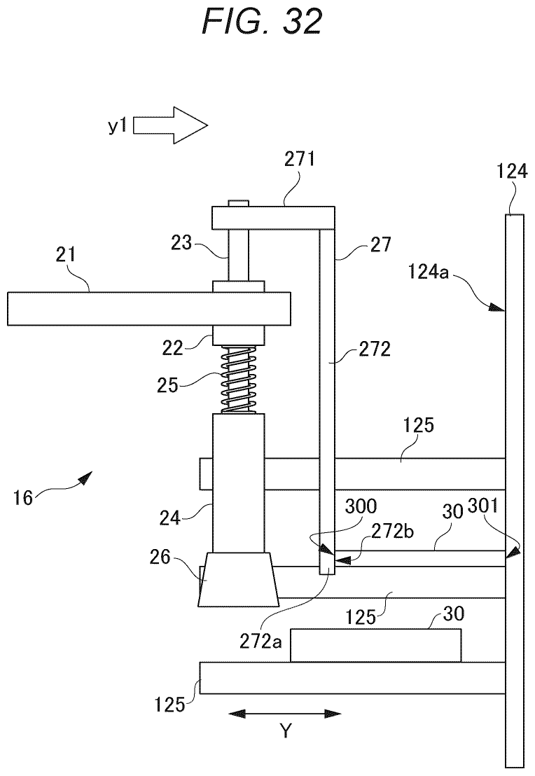

Next, the size detector 19S detects the size of the sample 30 stored in the takeout target stage in the cassette 12 serving as the pickup source (step S204). The takeout target stage is a stage from which the sample is to be taken out in the current measurement. In this case, the controller 17 drives the conveyance device 13 to horizontally move the hand portion 16 in the y1 direction (see FIG. 31). Accordingly, the pressing member 27 gradually approaches the back plate portion 124 of the cassette 12 serving as the placement destination while moving together with the hand portion 16. When the sample 30 is stored in the takeout target stage, as illustrated in FIG. 31, the contact surface 272b of the pressing member 27 comes into contact with the end surface 300 of the sample 30. Thereafter, the sample 30 is pressed by the pressing member 27 and moves in the y1 direction. During this movement, an end surface 301 of the sample 30 is pressed against the inner surface 124a of the back plate portion 124 as illustrated in FIGS. 7 and 32. Then, the torque acting on the hand portion 16 increases. The end surface 301 of the sample 30 is arranged facing the back side of the cassette 12.

On the other hand, during the movement of the hand portion 16, the controller 17 repeatedly compares the torque acting on the hand portion 16 with a predetermined torque threshold at predetermined time intervals to determine whether or not the sample 30 has been pressed against the back plate portion 124. Specifically, when the torque acting on the hand portion 16 is equal to or less than the predetermined torque threshold, the controller 17 determines that the sample 30 has not been pressed against the back plate portion 124. In this case, the controller 17 continues moving the hand portion 16. When the torque acting on the hand portion 16 exceeds the predetermined torque threshold, the controller 17 determines that the sample 30 has been pressed against the back plate portion 124. In this case, the controller 17 stops the movement of the hand portion 16. When the sample 30 is pressed against the back plate portion 124 of the cassette 12 by the pressing member 27, the size detector 19S detects a length from the contact surface 272b of the second arm portion 272 to the inner surface 124a of the back plate portion 124 as the size Ly (refer to FIG. 7) of the sample 30.

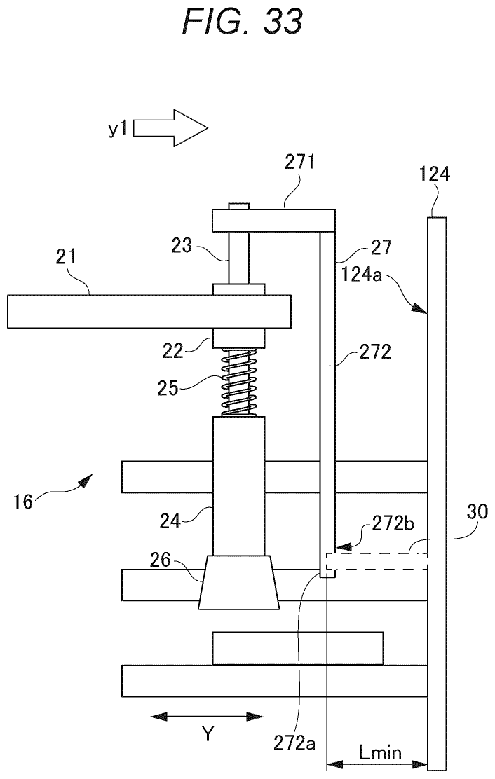

In addition, in a case where the sample 30 is not stored in the takeout target stage due to a mistake of the user, the pressing member 27 approaches the back plate portion 124 without contacting the sample 30. Therefore, the torque acting on the hand portion 16 does not exceed the predetermined torque threshold unless the pressing member 27 is pressed against the back plate portion 124 during the movement of the hand portion 16. In such a case, the size detector 19S detects (senses) that the size of the sample stored in the takeout target stage is smaller than the minimum sample size Lmin (see FIG. 33) before the pressing member 27 is pressed against the back plate portion 124. In other words, when detecting that the size of the sample stored in the takeout target stage is smaller than the minimum sample size Lmin, the size detector 19S determines that no sample 30 is stored in the takeout target stage. Then, the controller 17 stops the movement of the hand portion 16 before the pressing member 27 contacts the back plate portion 124.

The minimum sample size refers to the smallest size of a sample in the depth direction Y of the cassette 12 among sample sizes included in the sample information set by the user in the above step S201. FIG. 33 illustrates the sample 30 with the minimum sample size Lmin indicated by a dashed line.

Next, the controller 17 determines whether or not the size of the sample detected by the size detector 19S in the above step S204 is smaller than the minimum sample size (step S205). When the controller 17 makes a negative determination in step S205, the controller 17 proceeds to step S206. In addition, when the controller 17 makes an affirmative determination in step S205, the controller 17 proceeds to step S208. The case where the controller 17 proceeds from step S205 to step S208 corresponds to a case where the takeout target stage is skipped. Skipping the takeout target stage refers to switching to the next stage while skipping the one stage from which the sample is to be taken out.

In step S206, the controller 17 determines whether or not the size of the sample detected by the size detector 19S in the takeout target stage matches the size of the sample set for the takeout target stage by the user in step S201 described above. When the controller 17 makes an affirmative determination in step S206, the controller 17 proceeds to step S207. Then, in step S207, the controller 17 continues the sample measurement operation by the measuring device 11 and the conveyance device 13. When the controller 17 makes a negative determination in step S206, the controller 17 interrupts (stops) the sample measurement operation by the measuring device 11 and the conveyance device 13, and displays a warning (step S209). In step S209, the controller 17 displays, for example, a warning message “The size of the sample is different from the set size.” or the like on the display part of the operation part 18. Further, when displaying the warning in step S209, the controller 17 displays, on the display part of the operation part 18, information indicating a cassette for which the detected sample size does not match the set sample size and a stage for which the detected sample size does not match the set sample size. The sample measurement operation performed by the measuring device 11 and the conveyance device 13 will be described in detail later.

On the other hand, in step S208, the controller 17 determines whether or not the sample 30 subjected to the size detection in step S204 is the last sample. When the controller 17 makes a negative determination in step S208, the controller 17 returns to step S203. In addition, when the controller 17 makes an affirmative determination in step S208, the controller 17 ends the series of processing. The case where the controller 17 makes a negative determination in step S208 is a case where an unmeasured sample 30 remains in the cassette 12 serving as a pickup source.

Note that although not illustrated in FIG. 29, after checking the content of the warning displayed in step S209, the user can perform a predetermined operation to restart the sample measurement operation by the measuring device 11 and the conveyance device 13. The predetermined operation includes an operation for resolving a sample size error and an operation for instructing the controller 17 to restart the measurement via the operation part 18. The operation for resolving the sample size error is an operation in which the user re-sets correct sample information for the takeout target stage or re-sets the sample in the takeout target stage.

Here, the sample measurement operation by the measuring device 11 and the conveyance device 13 will be described in detail. A subject that controls the sample measurement operation is the controller 17, and objects controlled by the controller 17 are the measuring device 11 and the conveyance device 13.

First, the controller 17 causes the suction pad 26 of the hand portion 16 to suck a sample 30 stored in a takeout target stage of the cassette 12. In this case, the controller 17 causes the suction pad 26 to contact a sucked surface 30b (refer to FIG. 5) of the sample 30 by lowering the hand portion 16 toward the sample 30 to be taken out. In this case, when the suction pad 26 comes into contact with the sample 30 by the lowering of the hand portion 16 and the contact pressure exceeds a predetermined value, the spring 25 is compressed. Then, the suction pad 26 receives a reaction force due to the compression of the spring 25 and is pressed against the sample 30. Therefore, the suction pad 26 can be brought into close contact with the sample 30.

Next, the controller 17 causes the suction pad 26 to suck the sample 30 by causing the vacuum generator 24 to generate a vacuum suction force.

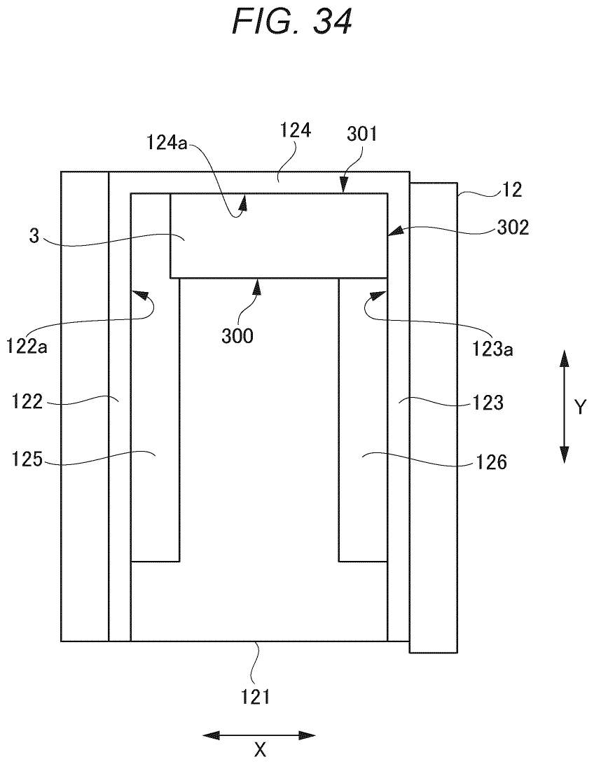

Next, the controller 17 moves the hand portion 16 in the width direction X of the cassette 12 to press the sample 30 against the side plate portion 123 as illustrated in FIG. 34. The side plate portion 123 corresponds to the reference end portion of the cassette 12 in the width direction X. In this case, the controller 17 moves the hand portion 16 in the width direction X of the cassette 12 while causing the suction pad 26 to suck the sample 30, thereby pressing a side end surface 302 of the sample 30 against the inner surface 123a of the side plate portion 123. Thus, the sample 30 stored in the takeout target stage is aligned in the width direction X of the cassette. In addition, when the size of the sample is to be detected in step S204, the sample 30 stored in the takeout target stage is pressed against the back plate portion 124 by the pressing member 27. Therefore, the sample 30 is aligned in both the width direction X of the cassette and the depth direction Y of the cassette.

Note that in the present embodiment, the controller 17 presses the sample 30 against the side plate portion 123 when the sample 30 is to be aligned in the width direction X of the cassette 12, but the present invention is not limited thereto, and the controller 17 may press the sample 30 against the side plate portion 122. That is, the reference end portion of the cassette 12 in the width direction X may be the side plate portion 122.

Next, the controller 17 releases the sucking of the sample 30 by the suction pad 26.

Next, the controller 17 raises the hand portion 16 by a predetermined amount such that a gap is secured between the suction pad 26 and the sample 30, and then moves the suction pad 26 to the center position of the sample 30. The center position of the sample 30 is the center position of the sucked surface 30b of the sample 30. In this case, the controller 17 specifics the center position of the sample 30 based on the sample size set for the takeout target stage by the user in the above step S201 and/or the size of the sample detected by the size detector S204 in the above step 19S. Furthermore, the controller 17 controls the driving of the conveyance device 13 such that the suction pad 26 is arranged at the specified center position of the sample 30.

Next, the controller 17 causes the suction pad 26 to suck the sample 30 by operating the hand portion 16 in the same manner as described above. In this case, the suction pad 26 sucks the center position of the sample 30. The position of the sample 30 sucked by the suction pad 26 may be a position of the sample 30 other than the center position of the sample 30 as long as handling of the sample 30 by the suction pad 26 and the measurement of the sample 30 by the measuring device 11 are not hindered.

Next, the controller 17 raises the hand portion 16 by a predetermined amount to slightly lift the sample 30 from the support portions 125 and 126. As a result, the sample 30 is picked up by the hand portion 16 in the takeout target stage.

Next, the controller 17 takes out the sample 30 from the takeout target stage of the cassette 12 by horizontally moving the hand portion 16 from the back side to the front side of the cassette 12.

Next, the controller 17 moves the sample 30 sucked by the suction pad 26 to the measurement position of the measuring device 11. In this case, the controller 17 controls the driving of the conveyance device 13 to align the surface 30a (see FIG. 5) of the sample 30 to be measured with the measurement section 15 of the measuring device 11. In addition, the controller 17 appropriately changes the posture and the position of the hand portion 16 to lightly press the surface 30a of the sample 30 to be measured against the measurement section 15 of the measuring device 11. Thus, the surface 30a of the sample 30 to be measured is arranged close to and faces the measurement section 15 of the measuring device 11. The suction pad 26 sucks the center position of the sample 30. Therefore, the controller 17 adjusts the position at which the sample 30 is sucked by the suction pad 26 to the center position of the measurement section 15 of the measuring device 11 by appropriately changing the posture and the position of the hand portion 16. That is, the controller 17 controls the conveyance device 13 such that the position of the sample 30 to be measured coincides with the position of the measuring device 11 that measures the sample 30.

Next, the controller 17 transmits a measurement command signal to the measuring device 11. Thus, the measuring device 11 measures the sample 30. In this case, the measuring device 11 irradiates the surface 30a of the sample 30 to be measured with light for measurement from a light source included in the measuring device 11. In addition, the measuring device 11 receives light reflected from the surface 30a to be measured with a sensor included in the measuring device 11. Thus, the measuring device 11 measures the surface condition of the sample 30. The configuration of the measuring device 11 may vary depending on what to measure in the sample 30. In the present embodiment, the position of the portion of the sample 30 to be sucked by the suction pad 26 is aligned with the center position of the measurement section 15 of the measuring device 11. Therefore, the surface condition of the sample 30 can be measured with respect to the center portion of the surface 30a of the sample 30 to be measured.

Next, the controller 17 causes the hand portion 16 to move to the front of the cassette 12 serving as the placement destination while sucking the measured sample 30 with the suction pad 26. In this case, the controller 17 aligns the hand portion 16 in accordance with the height position of a stage in which the measured sample 30 is to be stored among the plurality of stages of the cassette 12 serving as the placement destination.

Next, the controller 17 moves the suction pad 26 from the front side to the back side of the cassette 12 by the horizontal movement of the hand portion 16. Thus, the sample 30 enters the cassette 12. In this case, the controller 17 controls the amount of horizontal movement of the hand portion 16 based on the sample size set for the takeout target stage by the user in the above step S201 and/or the size of the sample detected by the size detector 19S in the above step S204. Next, the controller 17 lowers the hand portion 16 by a predetermined amount to lower

the sample 30 to the vicinity of the upper surfaces of the pair of support portions 125 and 126. The pair of support portions 125 and 126 described here are the support portions 125 and 126 that form the stage in which the measured sample 30 is to be stored.

Next, the controller 17 releases the sucking of the sample 30 by the suction pad 26. Thus, the sample 30 is supported (placed) on the pair of support portions 125 and 126.

Next, the controller 17 separates the suction pad 26 from the sample 30 by raising the hand portion 16 by a predetermined amount.

Next, the controller 17 moves the hand portion 16 to the home position.

Then, the sample measurement operation performed by the measuring device 11 and the conveyance device 13 ends.

When the size of the sample 30 is to be detected using the pressing member 27 as described above, the controller 17 may change, in accordance with the hardness of the sample 30, the torque threshold for determining whether or not the sample 30 has abutted against the back plate portion 124. Specifically, the controller 17 sets the torque threshold to a large value when the hardness of the sample 30 is high, and sets the torque threshold to a small value when the hardness of the sample 30 is low. Thus, even when samples 30 having different hardness are handled, whether or not the samples 30 have abutted against the back plate portion 124 can be appropriately determined. The hardness of the sample 30 may be included in the sample information, or may be specified (estimated) from the material of the sample 30.

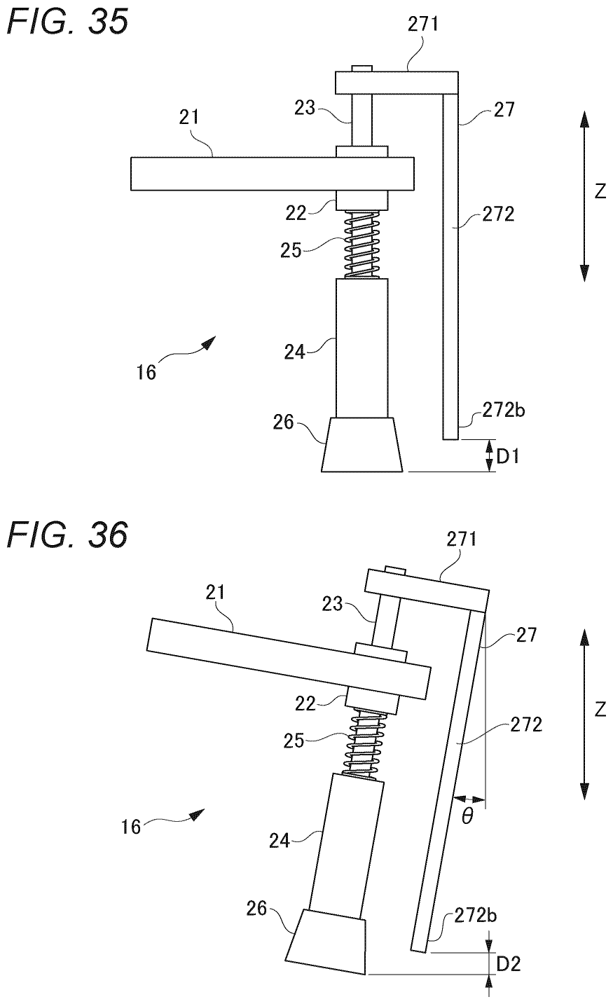

Furthermore, when the size of the sample 30 is to be detected by using the pressing member 27 as described above, the controller 17 may change the inclination angle of the pressing member 27 in accordance with the hardness of the sample 30. The inclination angle of the pressing member 27 is defined by the inclination angle of the pressing member 27 with respect to the height direction Z (vertical axis) of the cassette. As illustrated in FIG. 35, in a case where the second arm portion 272 of the pressing member 27 is not inclined with respect to the height direction Z of the cassette, the inclination angle of the pressing member 27 is zero. Further, as illustrated in FIG. 36, in a case where the second arm portion 272 of the pressing member 27 is inclined by an angle θ with respect to the height direction Z of the cassette, the inclination angle of the pressing member 27 is θ. The controller 17 sets the inclination angle of the pressing member 27 to a large value when the hardness of the sample is high, and sets the inclination angle of the pressing member 27 to a small value when the hardness of the sample is low.

When the inclination angle of the pressing member 27 is set to a large value (see FIG. 36), a length of a gap between the suction surface of the suction pad 26 and the lowest end portion of the pressing member 27 is smaller than that when the inclination angle is set to a small value (D1>D2) (see FIG. 35). Therefore, in a case where the inclination angle of the pressing member 27 is set to a large value, when the pressing member 27 is brought into contact with the sample 30 stored in the takeout target stage, the suction pad 26 is less likely to interfere with a sample 30 stored in a stage below the takeout target stage. However, in a case where the inclination angle of the pressing member 27 is set to a large value, when the sample 30 is pressed by the pressing member 27, an obliquely downward force is applied to the sample 30. Therefore, a sample 30 having low hardness is pressed and deformed by the pressing member 27, and there is a possibility that the size of the sample 30 may not be accurately detected. Therefore, when the sample 30 having low hardness is pressed by the pressing member 27, the controller 17 preferably sets the inclination angle of the pressing member 27 to a small value.

Furthermore, when the size of the sample 30 is to be detected using the pressing member 27 as described above, the controller 17 may change the pressing force of the pressing member 27 in accordance with the mass of the sample 30. Specifically, the controller 17 sets the pressing force of the pressing member 27 to a large value when the mass of the sample is large, and sets the pressing force of the pressing member 27 to a small value when the mass of the sample is small. Thus, the pressing member 27 can press samples 30 having different masses against the back plate portion 124 with an appropriate force. The pressing force of the pressing member 27 is a force applied from the pressing member 27 to the sample 30 when the pressing member 27 presses the sample 30 against the back plate portion 124.

Furthermore, when the size of the sample 30 is to be detected using the pressing member 27 as described above, the controller 17 may change the pressing force of the pressing member 27 in accordance with the friction coefficient of the sample 30. Specifically, the controller 17 sets the pressing force of the pressing member 27 to a large value when the friction coefficient of the sample 30 is large, and sets the pressing force of the pressing member 27 to a small value when the friction coefficient of the sample 30 is small. Thus, the pressing member 27 can press samples 30 having different friction coefficients against the back plate portion 124 with an appropriate force. The friction coefficient of the sample 30 may be included in the sample information, or may be specified (estimated) from the material of the sample 30.

Furthermore, when the size of the sample 30 is to be detected using the pressing member 27 as described above, the controller 17 may change, in accordance with the hardness of the sample 30, the number of times the pressing member 27 presses the sample 30. Specifically, when the hardness of the sample 30 is high, the controller 17 sets the number of times of pressing the sample 30 to be large, and when the hardness of the sample 30 is low, the controller 17 sets the number of times of pressing the sample 30 to be small. When the hardness of the sample 30 is high, the controller 17 sets the number of times of pressing the sample 30 to a plurality of times, and when the hardness of the sample 30 is low, the controller 17 sets the number of times of pressing the sample 30 to one time.

Here, a problem caused by the sample size error will be described. The sample size error is caused by a user's mistake as described above. To give a specific example, the sample size error occurs in a case where the user sets incorrect sample information for a takeout target stage (hereinafter, also referred to as “incorrect setting”). The sample size error also occurs in a case where the user sets a sample having a size different from a sample size set for the takeout target stage of the cassette serving as the pickup source (hereinafter, also referred to as “incorrect setting”). When the sample size error occurs, the hand portion 16 of the conveyance device 13 may not be able to appropriately handle the sample 30, and various problems may occur.

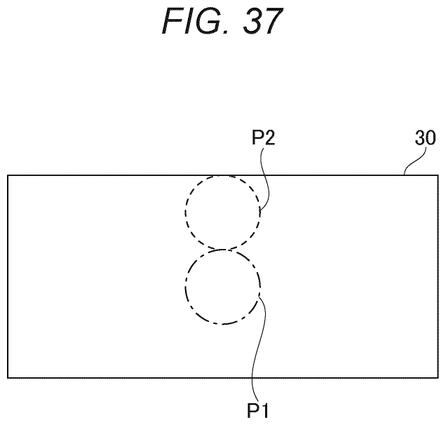

For example, when the sample size error occurs, as illustrated in FIG. 37, although the suction pad 26 should originally suck the center position P1 of the sample 30, the suction pad 26 may suck a position P2 greatly deviated from the center position P1. Therefore, the measuring device 11 may measure the surface condition of the sample 30 at the position of the position P2 deviated from the center position P1 of the sample 30 to be originally measured. Further, when the conveyance device 13 holds the sample 30 by vacuum suction, the suction pad 26 may unstably suck the sample 30 at the position P2. As a result, in the process in which the conveyance device 13 conveys the sample 30, the sample 30 may be dropped or damaged.

On the other hand, in the sample measuring apparatus 10A according to the fifth embodiment of the present invention, the size of a sample 30 stored in each stage of the cassette 12 serving as the pickup source is detected by the size detector 19S. Then, the controller 17 controls the measuring device 11 and the conveyance device 13 based on a result of the detection by the size detector 19S. Accordingly, the controller 17 can continue the sample measurement operation by the measuring device 11 and the conveyance device 13 after confirming that the size of the sample detected by the size detector 19S in the takeout target stage matches the sample size set for the takeout target stage by the user via the operation part 18. For this reason, even when the user makes an incorrect setting, it is possible to prevent the suction pad 26 from sucking the sample 30 at a position greatly deviated from the center position of the sample 30 or to prevent the measuring device 11 from measuring the sample 30 at the position of the position P2 deviated from the position of the center position P1 of the sample 30 to be originally measured. This also applies to a case where the user makes an incorrect setting. Therefore, with the sample measuring apparatus 10A according to the fifth embodiment, it is possible to avoid a problem caused by the sample size error.

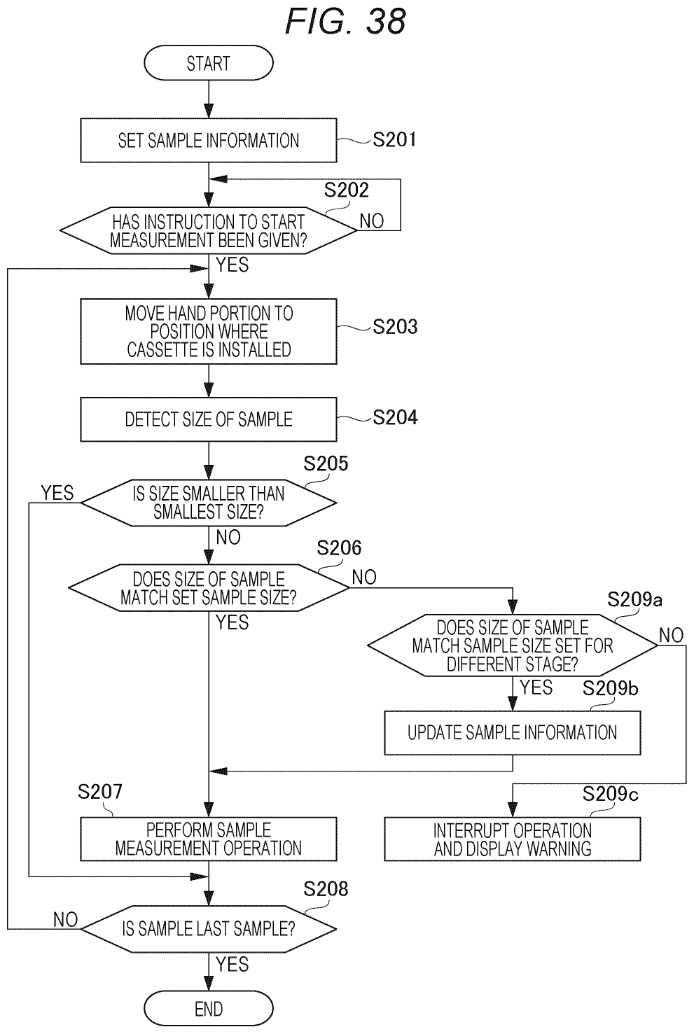

Note that in the fifth embodiment described above, the controller 17 interrupts the sample measurement operation by the measuring device 11 and the conveyance device 13 and displays a warning when the controller 17 makes a negative determination in step S206, as illustrated in FIG. 29, but the present invention is not limited thereto. For example, when the controller 17 makes a negative determination in step S206, the controller 17 may perform processing in accordance with the procedure illustrated in FIG. 38. To be specific, when the controller 17 makes a negative determination in step S206, the controller 17 determines whether or not the size of the sample detected by the size detector 19S in step S204 matches a sample size set by the user in step S201 for a different stage from the takeout target stage (step S209a). Here, the different stage from the takeout target stage refers to a stage located on the lower side of the takeout target stage, that is, a stage before the sample 30 is taken out.

Next, when the controller 17 makes an affirmative determination in step S209a, the controller 17 proceeds to step S209b. When the controller 17 makes a negative determination in step S209a, the controller 17 proceeds to step S209c. In step S209b, the controller 17 updates information (sample information) regarding the sample 30 stored in the takeout target stage and to be measured this time. As a result, the size of the sample 30 set for the takeout target stage is rewritten in accordance with the size of the sample detected by the size detector 19S in step

S204. Thereafter, the controller 17 continues the sample measurement operation by the measuring device 11 and the conveyance device 13 based on the updated sample information (step S207). The updated sample information includes the size of the sample rewritten as described above. Further, in step S209c, the controller 17 interrupts (stops) the sample measurement operation by the measuring device 11 and the conveyance device 13 and displays a warning.

### Sixth Embodiment

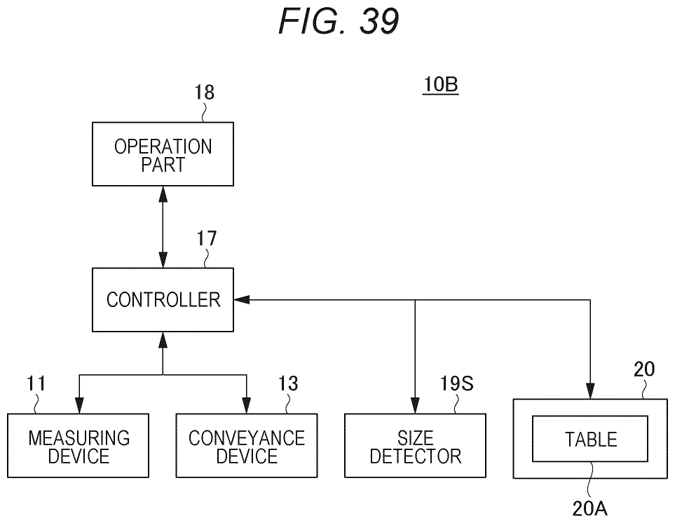

FIG. 39 is a block diagram illustrating a configuration of a control system of a sample measuring apparatus according to a sixth embodiment of the present invention.

As illustrated in FIG. 39, the sample measuring apparatus 10B includes a memory 20 in addition to the measuring device 11, the conveyance device 13, the controller 17, the operation part 18, and the size detector 19S.

The memory 20 stores a table 20A in advance. The memory 20 includes a nonvolatile memory. In the sample measuring apparatus 10B according to the sixth embodiment, it is not necessary for the user to set the sample information via the operation part 18.

The table 20A is stored in the memory 20 as a preferred example of registration information in which requirements for sizes of samples to be measured are registered for each sample type. Each sample type refers to a type of a sample. The table 20A is a table in which a sample type can be determined from the size of a sample detected by the size detector 19S. The size of the sample detected by the size detector 19S is the size of the sample in the depth direction Y of the cassette. The size of the sample in the depth direction Y of the cassette differs for each sample type.

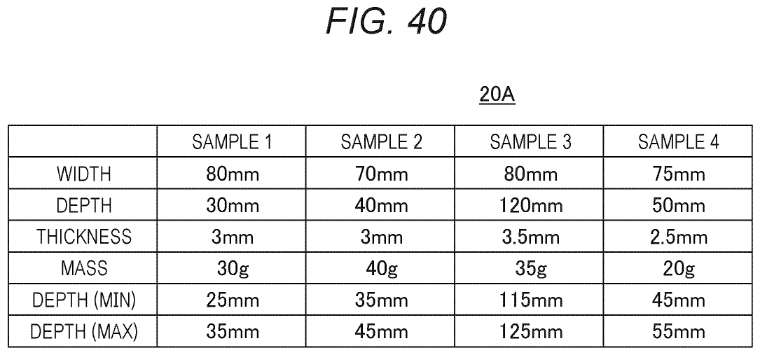

FIG. 40 is a diagram illustrating an example of the table.

As illustrated in FIG. 40, four sample types are registered in the table 20A. To be more specific, sample 1, sample 2, sample 3, and sample 4 are registered in the table 20A. Further, in the table 20A, the width of a sample, the depth of the sample, the thickness of the sample, the mass of the sample, and a requirement for the size of the sample are registered for each sample type. The width of the sample is the size of the sample in the width direction X of the cassette. The depth of the sample is the size of the sample in the depth direction Y of the cassette.

Sample 1 indicates a type of sample having a width of 80 mm, a depth of 30 mm, a thickness of 3 mm, and a mass of 30 g. A requirement for a size of a sample classified as Sample 1 is that the depth of the sample is in a range of 25 mm or more and less than 35 mm.

Sample 2 indicates a type of sample having a width of 70 mm, a depth of 40 mm, a thickness of 3 mm, and a mass of 40 g. A requirement for a size of a sample classified as Sample 2 is that the depth of the sample is in a range of 35 mm or more and less than 45 mm.

Sample 3 indicates a type of sample having a width of 80 mm, a depth of 120 mm, a thickness of 3.5 mm, and a mass of 35 g. A requirement for a size of a sample classified as Sample 3 is that the depth of the sample is in a range of 115 mm or more and less than 125 mm.

Sample 4 indicates a type of sample having a width of 75 mm, a depth of 50 mm, a thickness of 2.5 mm, and a mass of 20 g. A requirement for a size of a sample classified as the sample 4 is that the depth of the sample is in a range of 45 mm or more and less than 55 mm.

The reason why the requirements for the sizes of samples are defined by the maximum values and the minimum values is that the dimensions of the samples 30 to be actually produced may vary from design values, and errors may occur in the sizes of the samples to be detected by the size detector 19S.

Based on the size of a sample detected by the size detector 19S, the controller 17 can determine (specify) the type of the sample by referring to the table 20A. Specifically, the controller 17 determines the type of a sample whose depth is in a range of 25 mm or more and less than 35 mm to be “sample 1” and determines the type of a sample whose depth is in a range of 35 mm or more and less than 45 mm to be “sample 2”. In addition, the controller 17 determines the type of a sample whose depth is in a range of 115 mm or more and less than 125 mm to be “sample 3”, and determines the type of the sample whose depth is in a range of 45 mm or more and less than 55 mm to be “sample 4”. The number of sample types that can be determined using the table 20A can be changed.

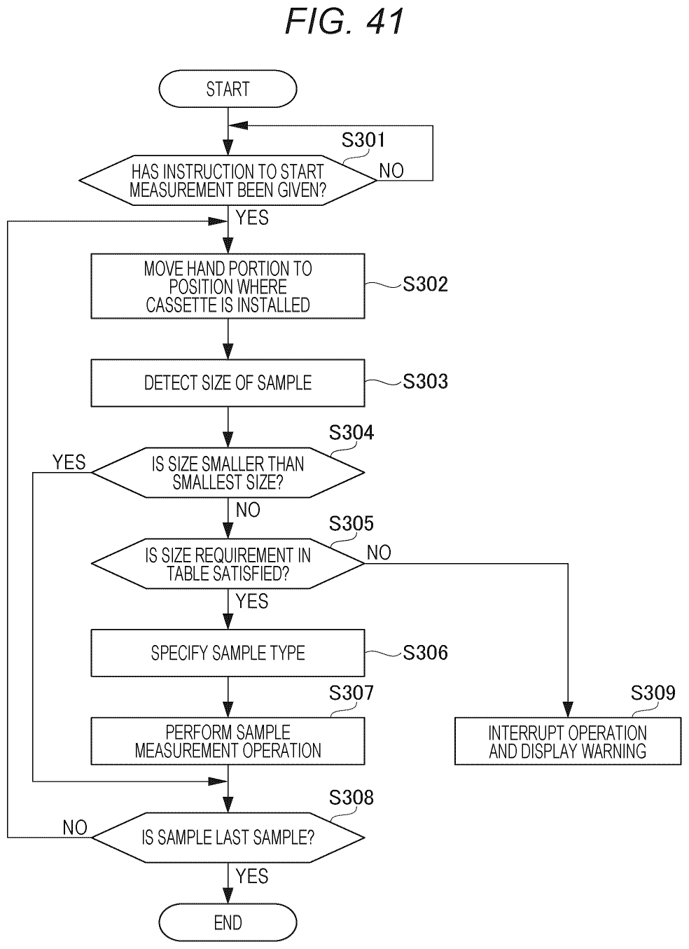

FIG. 41 is a flowchart illustrating an example of a processing procedure for measuring a sample using the sample measuring apparatus according to the sixth embodiment of the present invention. Note that the table 20A is stored in the memory 20 at the time of starting a series of processes illustrated in FIG. 41.

First, the controller 17 repeatedly determines whether or not an instruction to start measurement has been given (step S301). The processing in step S301 is the same as the processing in step S202 described above.

Next, the controller 17 drives the conveyance device 13 to move the hand portion 16 from the home position to the position where the cassette 12 serving as the pickup source is installed (step S302). The processing in step S302 is the same as the processing in step S203 described above.

Next, the size detector 19S detects the size of a sample 30 stored in the takeout target stage in the cassette 12 serving as the pickup source (step S303). The processing in step S303 is the same as the processing in step S204 described above.

Next, the controller 17 determines whether or not the size of the sample detected by the size detector 19S in the above step S303 is smaller than the minimum sample size (step S304).

The minimum sample size used in step S304 is the smallest size among the sample size requirements registered in the table 20A. In the table 20A illustrated in FIG. 40, the type of sample having the smallest depth is “sample 1”, and the smallest value of the sample size requirement registered in association with “sample 1” is 25 mm. Therefore, in step S304, the controller 17 determines whether or not the size of the sample detected by the size detector 19S is smaller than 25 mm. When the controller 17 makes a negative determination in step S304, the controller 17 proceeds to step S305. In addition, when the controller 17 makes an affirmative determination in step S304, the controller 17 proceeds to step S308. The case where the controller 17 proceeds from step S304 to step S308 corresponds to a case where the takeout target stage is skipped.

In step S305, the controller 17 determines whether or not the size of the sample detected by the size detector 19S in the takeout target stage satisfies any of the sample size requirements registered in the table 20A. To give a specific example, in a case where the size of the sample detected by the size detector 19S in the takeout target stage is 31 mm or 119 mm, the controller 17 makes an affirmative determination in step S305. In addition, in a case where the size of the sample detected by the size detector 19S in the takeout target stage is 100 mm or 150 mm, the controller 17 makes a negative determination in step S305.

The controller 17 having made an affirmative determination in step S305 specifies the type of the sample stored in the takeout target stage (step S306). In detail, the controller 17 specifies the type of the sample of which the size is detected by the size detector 19S by referring to the table 20A in the memory 20. For example, when the size of the sample detected by the size detector 19S in the takeout target stage is 31 mm, the controller 17 specifies the type of the sample stored in the takeout target stage as “sample 1”. Thus, the controller 17 can grasp information regarding the sample registered in the table 20A in association with the specified sample type. The information of the sample that can be grasped by the controller 17 includes the width, depth, thickness, and mass of the sample.

Next, the controller 17 continues the sample measurement operation by the measuring device and the conveyance device based on the size (width and depth) of the sample corresponding to the sample type specified as described above (step S307). When the controller 17 makes a negative determination in step S305, the controller 17 interrupts (stops) the sample measurement operation by the measuring device 11 and the conveyance device 13, and displays a warning (step S309). Since the sample measurement operation by the measuring device 11 and the conveyance device 13 is the same as the contents described in the fifth embodiment, the detailed description thereof will be omitted.

On the other hand, in step S308, the controller 17 determines whether or not the sample 30 subjected to the size detection in step S303 is the last sample. When the controller 17 makes a negative determination in step S308, the controller 17 returns to step S302. In addition, when the controller 17 makes an affirmative determination in step S308, the controller 17 ends the series of processing.

In the sample measuring apparatus 10B according to the sixth embodiment, the size of a sample 30 stored in each stage of the cassette 12 serving as the pickup source is detected by the size detector 19S. Then, the controller 17 controls the measuring device 11 and the conveyance device 13 based on a result of the detection by the size detector 19S. Accordingly, the controller 17 can continue the sample measurement operation by the measuring device 11 and the conveyance device 13 after confirming that the size of the sample detected by the size detector 19S in the takeout target stage satisfies any of the sample size requirements registered in the table 20A in the memory 20. Therefore, according to the sample measuring apparatus 10B according to the sixth embodiment, even in a case where the user does not set the sample information via the operation part 18, it is possible to avoid a problem caused by the sample size error.

### Seventh Embodiment

Subsequently, a seventh embodiment of the present invention will be described. A sample measuring apparatus according to the seventh embodiment is characterized by a configuration of a size detector. The size detector included in the sample measuring apparatus according to the seventh embodiment includes size detection sensors provided in the respective stages of each of the cassettes 12. Each of the size detection sensors is, for example, an array sensor or a pressure distribution sensor.

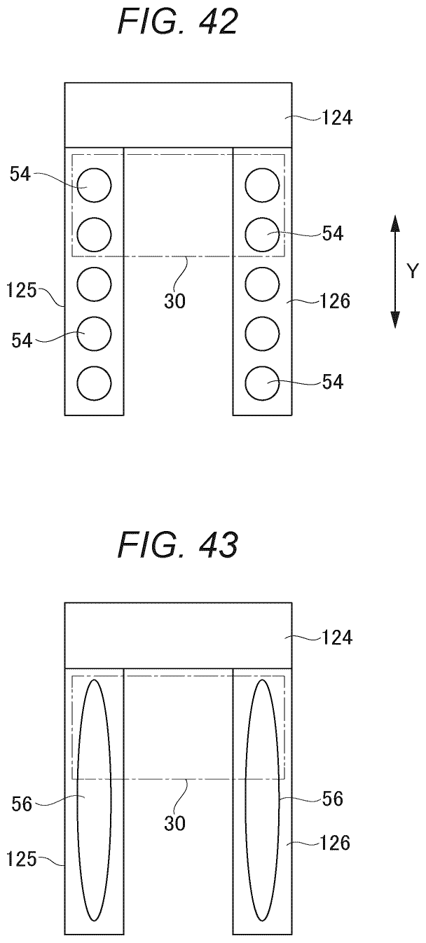

FIG. 42 is a schematic plan view illustrating an example in which each of the size detection sensors is an array sensor.

As illustrated in FIG. 42, each of the pair of support portions 125 and 126 is provided with a plurality of array sensors 54. Each of the array sensors 54 is, for example, a reflective photosensor. The plurality of array sensors 54 are arranged in the depth direction Y of the cassette. Each pair of support portions 125 and 126 form one stage in the cassette 12. The plurality of array sensors 54 are provided in all the stages (support portions 125 and 126) of each of the cassettes 12.

All of the plurality of array sensors 54 are in an off state in a state in which a sample 30 is not placed on the support portions 125 and 126. Further, among the plurality of array sensors 54, only an array sensor 54 overlapping with a sample 30 is in an on state in a state in which the sample 30 is placed on the support portions 125 and 126. In this case, the number of array sensors 54 to be turned on is determined by the size of the sample 30 in the depth direction Y of the cassette. Therefore, the size of the sample 30 can be detected by a difference in the number of array sensors 54 in an on state. Furthermore, when the number of array sensors 54 in an on state is zero, it can be determined that no sample 30 is stored in the stage formed by the pair of support portions 125 and 126.

FIG. 43 is a schematic plan view illustrating an example in which each of the size detection sensors is a pressure distribution sensor.

As illustrated in FIG. 43, each of the pair of support portions 125 and 126 is provided with a pressure distribution sensor 56. The pressure distribution sensor 56 is a film-shaped sensor that is long in the depth direction Y of the cassette. The pressure distribution sensors 56 are provided in all the stages (support portions 125 and 126) of each of the cassettes 12.

In each of the pressure distribution sensors 56, all sensor regions indicate uniformly low pressure values in a state in which a sample 30 is not placed on the support portions 125 and 126. Further, the pressure distribution sensor 56 indicates a high pressure value only in a sensor region overlapping with a sample 30 in a state in which the sample 30 is placed on the support portions 125 and 126. In this case, the area of a sensor region exhibiting a high pressure value is determined by the size of the sample 30 in the depth direction Y of the cassette. Therefore, the pressure distribution sensor 56 can detect the size of the sample 30 based on a difference in the area of the sensor region indicating a high pressure value. In addition, in a case where all the sensor regions indicate uniformly low pressure values, it can be determined that no sample 30 is stored in the stage formed by the pair of support portions 125 and 126.

Although embodiments of the present invention have been described and illustrated in detail, the disclosed embodiments are made for purposes of illustration and example only and not limitation. The scope of the present invention should be interpreted by terms of the appended claims.

What is claimed is:

1. A sample measuring apparatus comprising:
a measuring device that measures a sample;
a conveyance device that uses cassettes each having a plurality of stages capable of storing a plurality of samples having different sizes, takes out each sample one by one from a cassette serving as a pickup source among the cassettes, conveys the sample to the measuring device, and stores the sample measured by the measuring device into a cassette serving as a placement destination among the cassettes;
a sample detector capable of detecting presence or absence of the sample in each stage of each of the cassettes; and
a controller that controls the measuring device and the conveyance device based on a result of the detection by the sample detector.

2. The sample measuring apparatus according to claim 1, wherein the sample detector detects presence or absence of the sample in a predetermined stage of the cassette serving as the pickup source and/or a predetermined stage of the cassette serving as the placement destination.

3. The sample measuring apparatus according to claim 2, wherein the controller causes the measuring device and the conveyance device to perform a sample measurement operation when the sample is not present in the predetermined stage of the cassette serving as the pickup source and/or the predetermined stage of the cassette serving as the placement destination.

4. The sample measuring apparatus according to claim 2, wherein when the sample is present in the predetermined stage of the cassette serving as the pickup source and/or the predetermined stage of the cassette serving as the placement destination, the controller interrupts a sample measurement operation by the measuring device and the conveyance device and displays a warning.

5. The sample measuring apparatus according to claim 2, wherein the predetermined stage of the cassette serving as the pickup source is a stage on an upper side of a stage in which an unmeasured sample is stored, and the predetermined stage of the cassette serving as the placement destination is a stage on an upper side of the stage in which the measured sample is stored.

6. The sample measuring apparatus according to claim 1, wherein the sample detector moves to a position where the cassette serving as the pickup source or the cassette serving as the placement destination is installed, and detects the presence or absence of the sample.

7. The sample measuring apparatus according to claim 2, wherein the sample detector detects the presence or absence of the sample in the predetermined stage of the cassette serving as the pickup source before start of the taking-out of the sample from the cassette serving as the pickup source.

8. The sample measuring apparatus according to claim 2, wherein the sample detector detects the presence or absence of the sample in the predetermined stage of the cassette serving as the placement destination before start of the storing of the sample into the cassette serving as the placement destination.

9. The sample measuring apparatus according to claim 2, wherein
each of the cassettes has a reference end portion on a back side in a depth direction of the cassette,
the sample detector includes a pressing member capable of pressing the sample against the reference end portion of each of the cassettes, and
the sample detector determines that the sample is not present in the predetermined stage of each of the cassettes in a case where a length from the reference end portion of each of the cassettes to the pressing member is smaller than a minimum sample size.

10. The sample measuring apparatus according to claim 1, wherein
the conveyance device includes a hand portion for holding the sample,
the sample detector includes a distance measuring sensor attached to the hand portion, and
the distance measuring sensor measures a distance from the distance measuring sensor to an object in each stage of each of the cassettes in a depth direction of the cassette.

11. The sample measuring apparatus according to claim 1, wherein
the conveyance device includes a hand portion for holding the sample, and
the sample detector includes an imager that is attached to the hand portion and captures an image of the inside of each of the cassettes.

12. The sample measuring apparatus according to claim 1, comprising an operation part for a user to set sample information including a size of the sample stored in each stage of each of the cassettes.

13. The sample measuring apparatus according to claim 1, wherein the sample detector includes a sample detection sensor provided in each stage of each of the cassettes.

14. A sample measuring apparatus comprising:
a measuring device that measures a sample;
a conveyance device that takes out each sample one by one from a cassette having a plurality of stages capable of storing a plurality of samples having different sizes, and conveys the sample to the measuring device;
a size detector that detects a size of the sample stored in each stage of the cassette; and
a controller that controls the measuring device and the conveyance device based on a result of the detection by the size detector.

15. The sample measuring apparatus according to claim 14, further comprising an operation part for a user to set sample information including the size of the sample stored in each stage of the cassette.

16. The sample measuring apparatus according to claim 15, wherein the controller continues a sample measurement operation by the measuring device and the conveyance device when the size of the sample detected by the size detector in a takeout target stage matches a sample size set for the takeout target stage by the user via the operation part.

17. The sample measuring apparatus according to claim 15, wherein when the size of the sample detected by the size detector in a takeout target stage does not match a sample size set for the takeout target stage by the user via the operation part, the controller interrupts a sample measurement operation by the measuring device and the conveyance device, and displays a warning.

18. The sample measuring apparatus according to claim 15, wherein when the size of the sample detected by the size detector in a takeout target stage does not match a sample size set for the takeout target stage by the user via the operation part and matches a sample size set for a different stage from the takeout target stage by the user, the controller continues a sample measurement operation by the measuring device and the conveyance device based on the sample size set for the different stage.

19. The sample measuring apparatus according to claim 15, wherein when the size of the sample detected by the size detector in a takeout target stage is smaller than a minimum sample size among sample sizes included in sample information set by the user via the operation part, the controller skips the takeout target stage.

20. The sample measuring apparatus according to claim 14, further comprising a memory that stores, in advance, registration information in which a requirement for the size of the sample to be measured is registered for each sample type.

21. The sample measuring apparatus according to claim 14, wherein the size detector detects the size of the sample before the sample is taken out from a takeout target stage.

22. The sample measuring apparatus according to claim 14, wherein the size detector moves to a position where the cassette is installed, and detects the size of the sample.

23. The sample measuring apparatus according to claim 14, wherein the size detector includes a pressing member that presses the sample stored in a takeout target stage against a reference end portion of the cassette in a depth direction.

24. The sample measuring apparatus according to claim 14, wherein the size detector includes a size detection sensor provided in each stage of the cassette.
